(19) United States
(12) Patent Application Publication
(10) Pub. No.: US 2011/0049611 A1
(43) Pub. Date: Mar. 3, 2011

(54) NONVOLATILE SEMICONDUCTOR STORAGE DEVICE AND MANUFACTURING METHOD OF NONVOLATILE SEMICONDUCTOR STORAGE DEVICE

(75) Inventors: Masahiro Kiyotoshi, Mie (JP); Atsuhiro Kinoshita, Kanagawa (JP); Kiwamu Sakuma, Kanagawa (JP); Koichi Muraoka, Kanagawa (JP); Ichiro Mizushima, Kanagawa (JP)

(73) Assignee: KABUSHIKI KAISHA TOSHIBA, Tokyo (JP)

(21) Appl. No.: 12/769,951

(22) Filed: Apr. 29, 2010

(30) Foreign Application Priority Data
Aug. 27, 2009 (JP) 2009-197131

(51) Int. Cl. H01L 29/792; H01L 21/336

(52) U.S. Cl. 257/326; 438/287; 257/E29.309; 257/E21.423

(57) ABSTRACT

In a memory cell portion, a stacked structure, in which dielectric layers and semiconductor layers are alternately stacked, is arranged in a fin shape on a semiconductor substrate, and in a peripheral circuit portion, a gate electrode is arranged on the semiconductor substrate via a gate dielectric film so that a height of an upper surface of the gate electrode is set to be substantially equal to a height of an upper surface of the stacked structure in which the dielectric layers and the semiconductor layers are alternately stacked.

### CROSS-REFERENCE TO RELATED APPLICATIONS

This application is based upon and claims the benefit of priority from the prior Japanese Patent Application No. 2009-197131, filed on Aug. 27, 2009; the entire contents of which are incorporated herein by reference.

### BACKGROUND OF THE INVENTION

1. Field of the Invention

The present invention relates to a nonvolatile semiconductor storage device and a manufacturing method of the nonvolatile semiconductor storage device, and is particularly suitably applied to a stacked structure of a NAND-type flash memory.

2. Description of the Related Art

In a field of a NAND-type flash memory, a 3-dimensionally stacked-type memory attracts attention for achieving high bit density without being restricted by a resolution limit in a lithography technique. In order to reduce the number of processes in manufacturing the stacked-type memory, a method is proposed in which stacked active areas are collectively formed and control gate electrodes are collectively formed, and stacked memory layers are collectively selected by a floor select transistor (Japanese Patent Application Laid-open No. 2008-78404).

However, in a conventional stacked structure of the NAND-type flash memory, a memory cell portion becomes large in height, so that a step with respect to a peripheral circuit portion in which a select transistor or the like is formed becomes large. Therefore, an inter-layer dielectric film formed on the peripheral circuit portion increases in thickness for eliminating the step between the memory cell portion and the peripheral circuit portion, which makes it difficult to form a contact hole and fill a contact plug in some cases.

Moreover, in the stacked-type memory, ion implantation for forming a source and a drain in the peripheral circuit portion is performed before forming the memory cell portion. Therefore, the transistor characteristics of the peripheral circuit portion degrade in some cases due to a thermal process at the time of forming the memory cell portion.

### BRIEF SUMMARY OF THE INVENTION

A nonvolatile semiconductor storage device according to an embodiment of the present invention comprises: a memory cell portion in which a stacked structure, in which dielectric layers and semiconductor layers are alternately stacked, is arranged in a fin shape on a semiconductor substrate, a control gate electrode is arranged to intersect with the fin-shaped stacked structure and a charge storage layer is arranged between the fin shape and the control gate electrode; and a peripheral circuit portion in which a gate electrode is arranged on the semiconductor substrate via a gate dielectric film so that a height of an upper surface is substantially equal to the fin-shaped stacked structure.

A method of manufacturing a nonvolatile semiconductor storage device according to an embodiment of the present invention comprises: forming a gate electrode film of a peripheral circuit portion on a semiconductor substrate via a gate dielectric film; forming a fin-shaped stacked structure, in which dielectric layers and semiconductor layers are alternately stacked so that a height of an upper surface is substantially equal to the gate electrode film, in a memory cell portion; forming a charge storage layer on the fin-shaped stacked structure and the gate electrode film; forming an opening, which exposes at least a part of the gate electrode film, in the charge storage layer; forming a control gate electrode film electrically connected to the gate electrode film via the opening on the charge storage layer; and forming a first control gate electrode arranged on the charge storage layer to intersect with the fin-shaped stacked structure in the memory cell portion and forming a gate electrode, on an upper portion of which a second control gate electrode electrically connected via the opening is arranged, in the peripheral circuit portion, by collectively performing a patterning on the control gate electrode film, the charge storage layer, and the gate electrode film.

### BRIEF DESCRIPTION OF THE DRAWINGS

FIG. 1 is a perspective view illustrating a schematic configuration of a nonvolatile semiconductor storage device according to a first embodiment of the present invention;

FIG. 2A is a cross-sectional view illustrating a manufacturing method of the nonvolatile semiconductor storage device shown in FIG. 1;

FIG. 2B is a cross-sectional view taken along line A-A′ in FIG. 2A;

FIG. 2C is a cross-sectional view taken along line B-B′ in FIG. 2A;

FIG. 3A is a cross-sectional view illustrating the manufacturing method of the nonvolatile semiconductor storage device shown in FIG. 1;

FIG. 3B is a cross-sectional view taken along line A-A′ in FIG. 3A;

FIG. 3C is a cross-sectional view taken along line B-B′ in FIG. 3A;

FIG. 4A is a cross-sectional view illustrating the manufacturing method of the nonvolatile semiconductor storage device shown in FIG. 1;

FIG. 4B is a cross-sectional view taken along line A-A′ in FIG. 4A;

FIG. 4C is a cross-sectional view taken along line B-B′ in FIG. 4A;

FIG. 5A is a cross-sectional view illustrating the manufacturing method of the nonvolatile semiconductor storage device shown in FIG. 1;

FIG. 5B is a cross-sectional view taken along line A-A′ in FIG. 5A;

FIG. 5C is a cross-sectional view taken along line B-B′ in FIG. 5A;

FIG. 6A is a cross-sectional view illustrating the manufacturing method of the nonvolatile semiconductor storage device shown in FIG. 1;

FIG. 6B is a cross-sectional view taken along line A-A′ in FIG. 6A;

FIG. 6C is a cross-sectional view taken along line B-B′ in FIG. 6A;

FIG. 7A is a cross-sectional view illustrating the manufacturing method of the nonvolatile semiconductor storage device shown in FIG. 1;

FIG. 7B is a cross-sectional view taken along line A-A′ in FIG. 7A;

FIG. 7C is a cross-sectional view taken along line B-B′ in FIG. 7A;

FIG. 8A is a cross-sectional view illustrating the manufacturing method of the nonvolatile semiconductor storage device shown in FIG. 1;

FIG. 8B is a cross-sectional view taken along line A-A′ in FIG. 8A;

FIG. 8C is a cross-sectional view taken along line B-B′ in FIG. 8A;

FIG. 9A is a cross-sectional view illustrating the manufacturing method of the nonvolatile semiconductor storage device shown in FIG. 1;

FIG. 9B is a cross-sectional view taken along line A-A′ in FIG. 9A;

FIG. 9C is a cross-sectional view taken along line B-B′ in FIG. 9A;

FIG. 10A is a cross-sectional view illustrating the manufacturing method of the nonvolatile semiconductor storage device shown in FIG. 1;

FIG. 10B is a cross-sectional view taken along line A-A′ in FIG. 10A;

FIG. 10C is a cross-sectional view taken along line B-B′ in FIG. 10A;

FIG. 11 is a perspective view illustrating a schematic configuration of a nonvolatile semiconductor storage device according to a second embodiment of the present invention;

FIG. 12A is a cross-sectional view illustrating a manufacturing method of the nonvolatile semiconductor storage device shown in FIG. 11;

FIG. 12B is a cross-sectional view taken along line A-A′ in FIG. 12A;

FIG. 12C is a cross-sectional view taken along line B-B′ in FIG. 12A;

FIG. 13A is a cross-sectional view illustrating the manufacturing method of the nonvolatile semiconductor storage device shown in FIG. 11;

FIG. 13B is a cross-sectional view taken along line A-A′ in FIG. 13A;

FIG. 13C is a cross-sectional view taken along line B-B′ in FIG. 13A;

FIG. 14A is a cross-sectional view illustrating the manufacturing method of the nonvolatile semiconductor storage device shown in FIG. 11;

FIG. 14B is a cross-sectional view taken along line A-A′ in FIG. 14A;

FIG. 14C is a cross-sectional view taken along line B-B′ in FIG. 14A;

FIG. 15A is a cross-sectional view illustrating the manufacturing method of the nonvolatile semiconductor storage device shown in FIG. 11;

FIG. 15B is a cross-sectional view taken along line A-A′ in FIG. 15A;

FIG. 15C is a cross-sectional view taken along line B-B′ in FIG. 15A;

FIG. 16A is a cross-sectional view illustrating the manufacturing method of the nonvolatile semiconductor storage device shown in FIG. 11;

FIG. 16B is a cross-sectional view taken along line A-A′ in FIG. 16A;

FIG. 16C is a cross-sectional view taken along line B-B′ in FIG. 16A;

FIG. 17A is a cross-sectional view illustrating the manufacturing method of the nonvolatile semiconductor storage device shown in FIG. 11;

FIG. 17B is a cross-sectional view taken along line A-A′ in FIG. 17A;

FIG. 17C is a cross-sectional view taken along line B-B′ in FIG. 17A;

FIG. 18A is a cross-sectional view illustrating the manufacturing method of the nonvolatile semiconductor storage device shown in FIG. 11;

FIG. 18B is a cross-sectional view taken along line A-A′ in FIG. 18A;

FIG. 18C is a cross-sectional view taken along line B-B′ in FIG. 18A;

FIG. 19A is a cross-sectional view illustrating the manufacturing method of the nonvolatile semiconductor storage device shown in FIG. 11;

FIG. 19B is a cross-sectional view taken along line A-A′ in FIG. 19A;

FIG. 19C is a cross-sectional view taken along line B-B′ in FIG. 19A;

FIG. 20A is a cross-sectional view illustrating a manufacturing method of a nonvolatile semiconductor storage device according to a third embodiment of the present invention;

FIG. 20B is a cross-sectional view taken along line A-A′ in FIG. 20A;

FIG. 20C is a cross-sectional view taken along line B-B′ in FIG. 20A;

FIG. 21A is a cross-sectional view illustrating the manufacturing method of the nonvolatile semiconductor storage device according to the third embodiment of the present invention;

FIG. 21B is a cross-sectional view taken along line A-A′ in FIG. 21A;

FIG. 21C is a cross-sectional view taken along line B-B′ in FIG. 21A;

FIG. 22A is a cross-sectional view illustrating the manufacturing method of the nonvolatile semiconductor storage device according to the third embodiment of the present invention;

FIG. 22B is a cross-sectional view taken along line A-A′ in FIG. 22A;

FIG. 22C is a cross-sectional view taken along line B-B′ in FIG. 22A;

FIG. 23A is a cross-sectional view illustrating the manufacturing method of the nonvolatile semiconductor storage device according to the third embodiment of the present invention;

FIG. 23B is a cross-sectional view taken along line A-A′ in FIG. 23A;

FIG. 23C is a cross-sectional view taken along line B-B′ in FIG. 23A;

FIG. 24A is a cross-sectional view illustrating the manufacturing method of the nonvolatile semiconductor storage device according to the third embodiment of the present invention;

FIG. 24B is a cross-sectional view taken along line A-A′ in FIG. 24A;

FIG. 24C is a cross-sectional view taken along line B-B′ in FIG. 24A;

FIG. 25A is a cross-sectional view illustrating the manufacturing method of the nonvolatile semiconductor storage device according to the third embodiment of the present invention;

FIG. 25B is a cross-sectional view taken along line A-A′ in FIG. 25A;

FIG. 25C is a cross-sectional view taken along line B-B′ in FIG. 25A;

FIG. 26A is a cross-sectional view illustrating the manufacturing method of the nonvolatile semiconductor storage device according to the third embodiment of the present invention;

FIG. 26B is a cross-sectional view taken along line A-A′ in FIG. 26A;

FIG. 26C is a cross-sectional view taken along line B-B′ in FIG. 26A;

FIG. 27A is a cross-sectional view illustrating a manufacturing method of a nonvolatile semiconductor storage device according to a fourth embodiment of the present invention;

FIG. 27B is a cross-sectional view taken along line A-A′ in FIG. 27A;

FIG. 27C is a cross-sectional view taken along line B-B′ in FIG. 27A;

FIG. 28A is a cross-sectional view illustrating the manufacturing method of the nonvolatile semiconductor storage device according to the fourth embodiment of the present invention;

FIG. 28B is a cross-sectional view taken along line A-A′ in FIG. 28A;

FIG. 28C is a cross-sectional view taken along line B-B′ in FIG. 28A;

FIG. 29A is a cross-sectional view illustrating the manufacturing method of the nonvolatile semiconductor storage device according to the fourth embodiment of the present invention;

FIG. 29B is a cross-sectional view taken along line A-A′ in FIG. 29A;

FIG. 29C is a cross-sectional view taken along line B-B′ in FIG. 29A;

FIG. 30A is a cross-sectional view illustrating the manufacturing method of the nonvolatile semiconductor storage device according to the fourth embodiment of the present invention;

FIG. 30B is a cross-sectional view taken along line A-A′ in FIG. 30A;

FIG. 30C is a cross-sectional view taken along line B-B′ in FIG. 30A;

FIG. 31A is a cross-sectional view illustrating the manufacturing method of the nonvolatile semiconductor storage device according to the fourth embodiment of the present invention;

FIG. 31B is a cross-sectional view taken along line A-A′ in FIG. 31A;

FIG. 31C is a cross-sectional view taken along line B-B′ in FIG. 31A;

FIG. 32A is a cross-sectional view illustrating the manufacturing method of the nonvolatile semiconductor storage device according to the fourth embodiment of the present invention;

FIG. 32B is a cross-sectional view taken along line A-A′ in FIG. 32A;

FIG. 32C is a cross-sectional view taken along line B-B′ in FIG. 32A;

FIG. 33A is a cross-sectional view illustrating the manufacturing method of the nonvolatile semiconductor storage device according to the fourth embodiment of the present invention;

FIG. 33B is a cross-sectional view taken along line A-A′ in FIG. 33A; and

FIG. 33C is a cross-sectional view taken along line B-B′ in FIG. 33A.

### DETAILED DESCRIPTION OF THE INVENTION

A nonvolatile semiconductor storage device according to embodiments of the present invention is explained below with reference to the drawings. The present invention is not limited to theses embodiments.

### First Embodiment

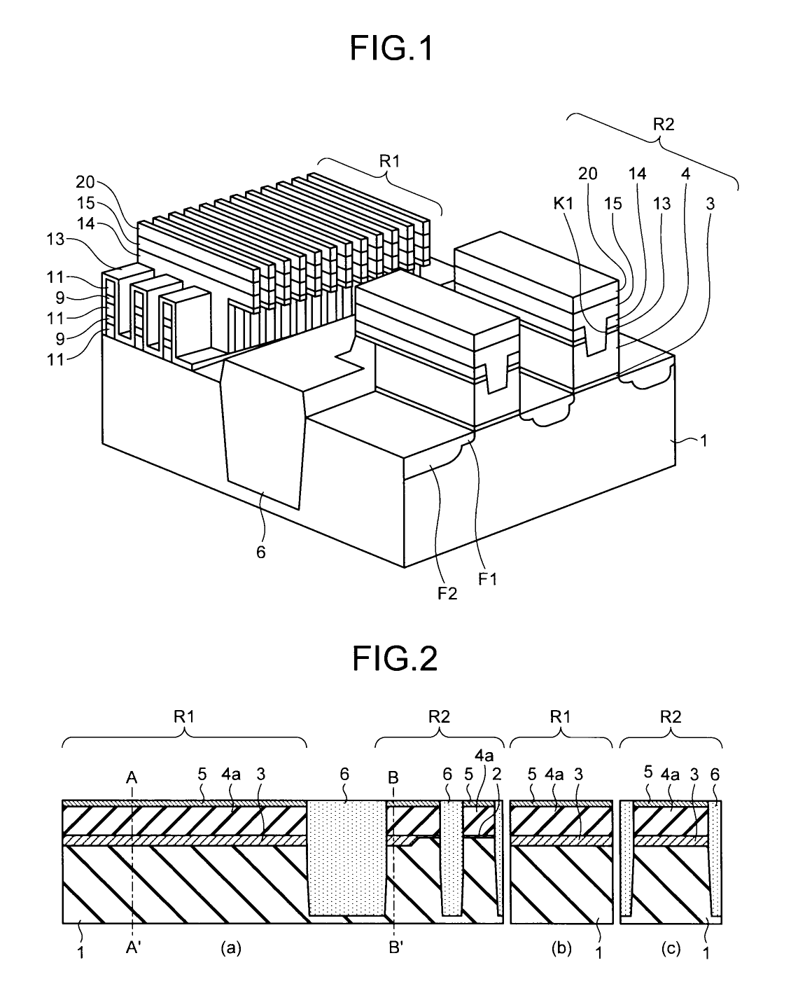

FIG. 1 is a perspective view illustrating a schematic configuration of a nonvolatile semiconductor storage device according to the first embodiment of the present invention.

In FIG. 1, a memory cell portion R1 in which memory cells of a NAND-type flash memory or the like is formed and a peripheral circuit portion R2 in which a peripheral circuit such as a select transistor is formed are provided on a semiconductor substrate 1. A dielectric film 6 is filled in the semiconductor substrate 1 to form a Shallow Trench Isolation (STI) at a boundary between the memory cell portion R1 and the peripheral circuit portion R2, so that the memory cell portion R1 and the peripheral circuit portion R2 are isolated.

In the memory cell portion R1, a stacked structure in which dielectric layers 11 and semiconductor layers 9 are alternately stacked is arranged in a fin shape on the semiconductor substrate 1. Moreover, in the memory cell portion R1, control gate electrodes 14 and 15 are arranged to intersect with this fin-shaped stacked structure on a charge storage layer 13. The control gate electrodes 14 are arranged over the side surfaces of the semiconductor layers 9 on the charge storage layer 13, so that channel regions can be formed on the side surfaces of the semiconductor layers 9. The material of the semiconductor substrate 1 and the semiconductor layer 9 can be selected from, for example, Si, Ge, SiGe, SiC, SiSn, PbS, GaAs, InP, GaP, GaN, ZnSe, and InGaAsP. Moreover, the semiconductor layer 9 can be composed of a monocrystalline semiconductor, a polycrystalline semiconductor, or a continuous grain semiconductor. The continuous grain semiconductor can be formed by crystallizing a polycrystalline silicon film by a laser annealing method or a metal induced crystallization (MIC)method using catalyst such as Ni. As the charge storage layer 13, for example, a silicon oxide film/silicon nitride film/silicon oxide film (ONO) structure, an aluminum oxide film/silicon nitride film/silicon oxide film (ANO) structure, or a floating gate structure can be used. Alternatively, a metal oxide film, such as HfO₂, La₂O₃, Pr₂O₃, Y₂O₃, and ZrO₂, or a film in which a plurality of such metal oxide films is combined can be used as the charge storage layer 13. As the material of the dielectric layer 11, for example, a silicon oxide film or an organic film can be used. As the material of the control gate electrodes 14 and 15, for example, polycrystalline silicon can be used. A silicide film 20 is formed on the control gate electrode 15 of the memory cell portion R1.

On the other hand, in the peripheral circuit portion R2, a gate electrode 4 is arranged on the semiconductor substrate 1 via a gate dielectric film 3. The charge storage layer 13, the control gate electrodes 14 and 15, and the silicide film 20 are stacked in order on the gate electrode 4. A metal film, such as W/TiN/Ti, TiN/Ti, WSi, and W/TaN can be used instead of the silicide film 20.

An opening K1 is formed in the charge storage layer 13 and the control gate electrode 14 to expose the gate electrode 4. The control gate electrode 15 of the peripheral circuit portion R2 is connected to the gate electrode 4 via the opening K1. In the semiconductor substrate 1 of the peripheral circuit portion R2, a high-concentration impurity diffusion layer F2 arranged on both sides of the gate electrode 4 via an LDD layer F1 is formed. The high-concentration impurity diffusion layer F2 can be used as a source and a drain of a field-effect transistor formed in the peripheral circuit portion R2.

The height of the upper surface of the gate electrode 4 on the semiconductor substrate 1 can be set to be substantially equal to the height of the upper surface of the stacked structure in which the dielectric layers 11 and the semiconductor layers 9 are alternately stacked.

With this structure, even when the dielectric layers 11 and the semiconductor layers 9 are alternately stacked on the semiconductor substrate 1, the step between the memory cell portion R1 and the peripheral circuit portion R2 can be reduced. Therefore, it is possible to form the LDD layer F1 and the high-concentration impurity diffusion layer F2 in the semiconductor substrate 1 after forming the stacked structure in which the dielectric layers 11 and the semiconductor layers 9 are alternately stacked on the semiconductor substrate 1, enabling to prevent the transistor characteristics of the peripheral circuit portion R2 from degrading due to the thermal process at the time of forming the memory cell portion R1.

FIG. 2A to FIG. 10A are cross-sectional views illustrating a manufacturing method of the nonvolatile semiconductor storage device shown in FIG. 1, FIG. 2B to FIG. 10B are cross-sectional views taken along lines A-A′ in FIG. 2A to FIG. 10A, respectively, and FIG. 2C to FIG. 100 are cross-sectional views taken along lines B-B′ in FIG. 2A to FIG. 10A, respectively. In this manufacturing method, a flash memory is taken as an example, which realizes a cell area of 1320 nm² that is equivalent to hp(half pitch) 19 nm generation in a planar cell structure by stacking two layers of a memory cell designed such that a half pitch of a bit line is 32 nm and a half pitch of a word line is 22 nm.

In FIG. 2, a recess is formed in the memory cell portion R1 and the peripheral circuit portion R2 on the semiconductor substrate 1 by a lithography technique and a reactive ion etching technique. The depth of the recess can be set to, for example, about 25 nm. This process is performed to eliminate the step due to the gate oxide film thickness in a high voltage circuit portion and a low voltage circuit portion of the flash memory.

Next, the gate dielectric film 3 is formed on the semiconductor substrate 1 by performing a thermal oxidation on the semiconductor substrate 1. Then, the gate dielectric film 3 of the low voltage circuit portion of the peripheral circuit portion R2 is removed by the lithography technique and a wet etching technology. Then, a gate dielectric film 2 is formed on the semiconductor substrate 1 of the low voltage circuit portion of the peripheral circuit portion R2 by performing the thermal oxidation on the semiconductor substrate 1. As the gate dielectric films 2 and 3, for example, a silicon thermally-oxidized film can be used. The film thickness of the gate dielectric film 2 can be set to, for example, about 6 nm. The film thickness of the gate dielectric film 3 after forming the gate dielectric film 2 can be set to, for example, about 40 nm.

Next, a gate electrode film 4a is formed on the gate dielectric films 2 and 3 by a method such as the CVD. As the gate electrode film 4a, for example, an n-type polycrystalline silicon film can be used. The film thickness of the gate electrode film 4a can be set to, for example, about 110 nm.

Next, a CMP stopper film 5 is formed on the gate electrode film 4a by a method such as the CVD. As the CMP stopper film 5, for example, a silicon nitride film can be used. The film thickness of the CMP stopper film 5 can be set to, for example, about 30 nm.

Next, an isolation trench is formed in the CMP stopper film 5, the gate electrode film 4a, the gate dielectric films 2 and 3, and the semiconductor substrate 1 by the lithography technique and the reactive ion etching technique. Then, the dielectric film 6 filled in the isolation trench is formed by a method such as the CVD. Then, the dielectric film 6 is polished by the CMP until the CMP stopper film 5 is exposed to form the STI structure that isolates the peripheral circuit portion R2 on the semiconductor substrate 1. As the dielectric film 6, for example, a high density plasma enhanced CVD SiO₂ (HDP-CVD SiO₂) film or a TEOS-O₃ film can be used.

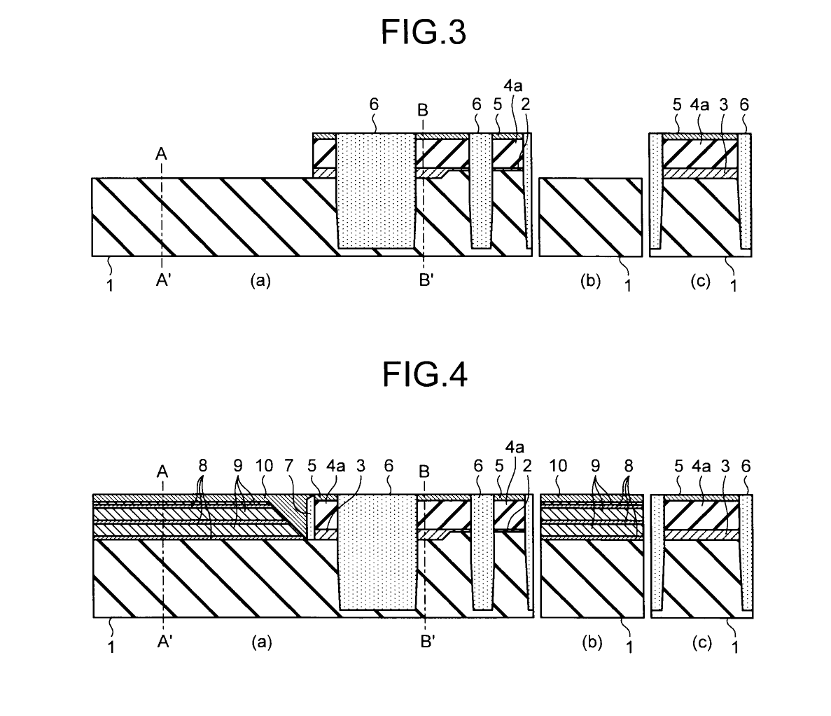

Next, as shown in FIG. 3, the CMP stopper film 5, the gate electrode film 4a, and the gate dielectric film 3 of the memory cell portion R1 are removed by the lithography technique and the reactive ion etching technique to expose the semiconductor substrate 1 of the memory cell portion R1.

Next, as shown in FIG. 4, an HTO film is formed on the semiconductor substrate 1 by a method such as the CVD. Then, the HTO film is etched back while leaving a side wall thereof by the reactive ion etching technique, whereby a side wall 7 is formed on the side faces of the CMP stopper film 5, the gate electrode film 4a, and the gate dielectric film 3, and the HTO film on the semiconductor substrate 1 is removed. Then, the clean surface of the semiconductor substrate 1 is exposed by a dilute hydrofluoric acid treatment.

Next, semiconductor layers 8 and 9 are alternately stacked on the semiconductor substrate 1 of the memory cell portion R1 by the LPCVD method. A material having a higher etching rate than the semiconductor layer 9 can be used for the semiconductor layer 8. As a material of the semiconductor layers 8 and 9, for example, a lattice matched combination selected from among Si, Ge, SiGe, SiC, SiSn, PbS, GaAs, InP, GaP, GaN, ZnSe, and GaInAsP can be used. For example, the material of the semiconductor layers 8 and 9 can be a combination of Si and SiGe, a combination of GaAs and GaAlAs, or a combination of GaInAsP and InP. Particularly, when the semiconductor substrate 1 is Si, it is preferable to use SiGe for the semiconductor layer 8 and Si for the semiconductor layer 9. The film thickness of the semiconductor layers 8 and 9 can be set to, for example, 20 nm, 45 nm, 20 nm, 45 nm, 20 nm, and 10 nm in order from the bottom. At this time, every time each layer of the semiconductor layers 9 is formed, impurities can be locally doped in the semiconductor layer 9 by an ion implantation or the like. Specially, the connection of each layer of the semiconductor layers 9 to the peripheral circuit can be controlled independently by forming an impurity diffusion layer at a different location for each layer of the stacked semiconductor layers 9. For example, when the semiconductor layer 9 is composed of p-type Si, n-type impurities, such as As and P, are ion-implanted.

Because the semiconductor layers 8 and 9 are not epitaxially grown around the side wall 7 and semiconductor layers 8 and 9 growing speed is dependent on their crystal orientation, an inclined surface is formed around the stacked structure of the semiconductor layers 8 and 9, and a wedge-shaped concave portion is formed between the side wall 7 and the stacked structure of the semiconductor layers 8 and 9.

Next, a planarization film 10 is formed on the semiconductor substrate 1 by a method such as the CVD. As the planarization film 10, for example, a silicon oxide film can be used. Then, the planarization film 10 is polished by a method such as the CVD until the CMP stopper film 5 is exposed to planarize the memory cell portion R1. The planarization film 10 can be filled in the wedge-shaped concave portion between the side wall 7 and the stacked structure of the semiconductor layers 8 and 9 to surround the periphery of the stacked structure of the semiconductor layers 8 and 9.

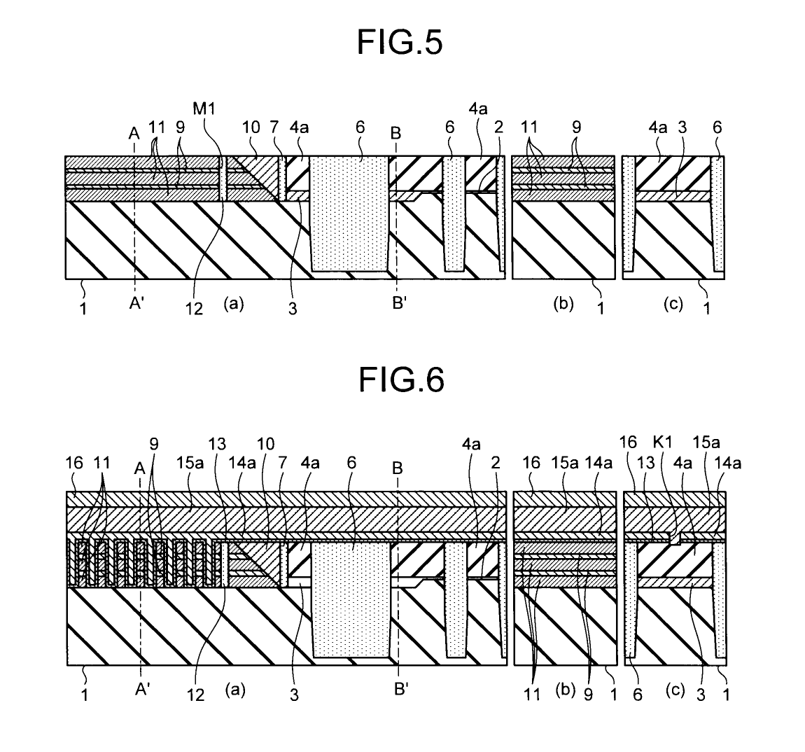

Next, as shown in FIG. 5, trenches M1 arranged in a predetermined direction at predetermined intervals are formed in the stacked structure of the semiconductor layers 8 and 9 by the lithography technique and the reactive ion etching technique to expose the side walls of the semiconductor layers 8 and 9 at predetermined intervals. Then, the semiconductor layers 8 are selectively removed by the wet etching to form a space between the semiconductor layers 9. For example, a mixture of hydrofluoric acid/nitric acid/acetic acid can be used as a chemical for the wet etching. Alternatively, the semiconductor layers 8 can be selectively removed by the Chemical Dry Etching (CDE). Still alternatively, the semiconductor layers 8 can be selectively removed by a gas etching with chlorine gas.

The planarization film 10 is filled to surround the stacked structure of the semiconductor layers 8 and 9, so that even when the space is formed between the semiconductor layers 9, both ends of the semiconductor layers 9 can be supported by the planarization film 10, enabling to prevent the semiconductor layers 9 from collapsing.

Next, the dielectric layers 11 filled between the semiconductor layers 9 are formed by performing a steam oxidation on the upper and lower surfaces of the semiconductor layers 9 via the trenches M1. As the dielectric layer 11, for example, a silicon thermally-oxidized film can be used. As a method for forming the dielectric layers 11 filled between the semiconductor layers 9, the CVD method or the ALD method can be used other than the steam oxidation of the semiconductor layers 9. Alternatively, an SOG film can be filled by a coating process, or a liquid organic dielectric film can be injected into the space between the semiconductor layers 9 and then cured.

Next, a dielectric film 12 filled in the trenches M1 is formed by a method such as the CVD. As the dielectric film 12, for example, a silicon oxide film can be used. Then, the dielectric film 12 and the CMP stopper film 5 are etched back by the reactive ion etching to expose the gate electrode film 4a of the peripheral circuit portion R2.

Next, as shown in FIG. 6, the stacked structure of the semiconductor layers 9 and the dielectric layers 11 is processed into a fin shape by the lithography technique and the reactive ion etching to expose the side surfaces of the semiconductor layers 9. The width of this fin-shaped structure can be set to, for example, 20 nm. The half pitch of this fin-shaped structure can be set to, for example, 32 nm.

Next, after performing a pretreatment with dilute hydrofluoric acid, the charge storage layer 13 is formed on the stacked structure of the semiconductor layers 9 and the dielectric layers 11 and the gate electrode film 4a by a method such as the CVD so that the side surfaces of the semiconductor layers 9 are covered. As the charge storage layer 13, for example, the ONO structure formed of the silicon oxide film/silicon nitride film/silicon oxide film can be used, and the film thickness at this time can be set to, for example, 3 nm, 2 nm, and 8 nm in order from the bottom.

Next, a control gate electrode film 14a is formed on the charge storage layer 13 by a method such as the CVD. As the control gate electrode film 14a, for example, an n-type polycrystalline silicon film can be used. The thickness of the control gate electrode film 14a can be set to, for example, about 40 nm.

Next, the opening K1 that exposes the gate electrode film 4a of the peripheral circuit portion R2 is formed in the charge storage layer 13 and the control gate electrode film 14a by the lithography technique and the reactive ion etching.

Next, a control gate electrode film 15a connected to the gate electrode film 4a via the opening K1 is formed on the control gate electrode film 14a by a method such as the CVD. As the control gate electrode film 15a, for example, an n-type polycrystalline silicon film can be used. The thickness of the control gate electrode film 15a can be set to, for example, about 150 nm.

Next, a hard mask film 16 is formed on the control gate electrode film 15a by a method such as the CVD. As the hard mask film 16, for example, a silicon nitride film can be used. The thickness of the hard mask film 16 can be set to, for example, about 100 nm.

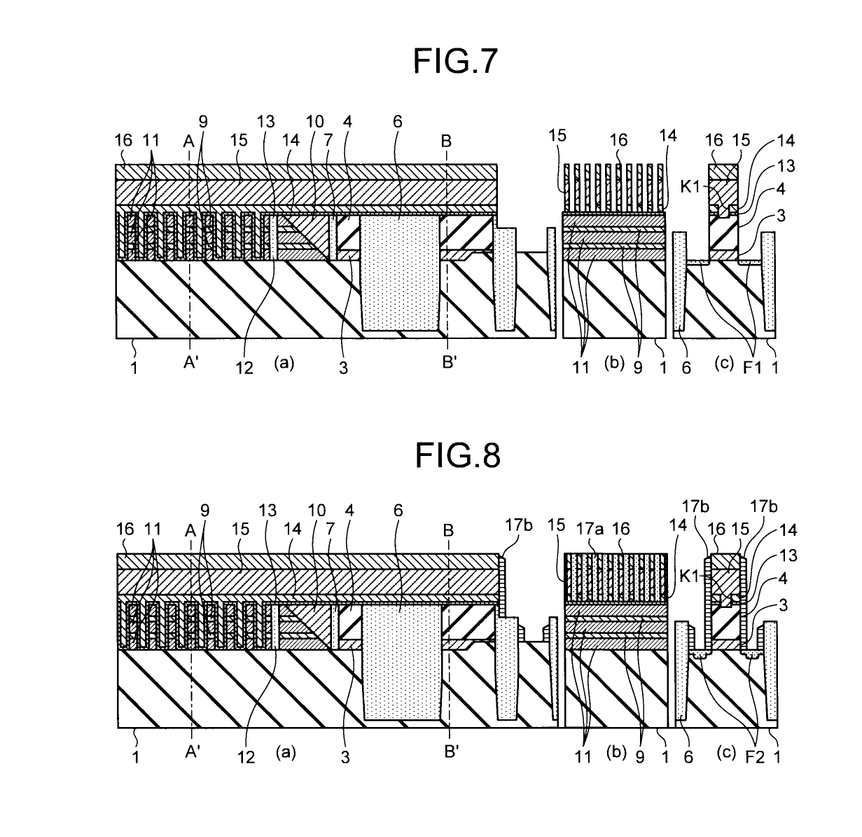

Next, as shown in FIG. 7, a patterning is performed on the hard mask film 16 to correspond to the planar shape of the gate electrode 4 and the control gate electrodes 14 and 15 by the lithography technique and the reactive ion etching technique. Then, the reactive ion etching of the control gate electrode films 15a and 14a, the charge storage layer 13, and the gate electrode film 4a is collectively performed via the hard mask film 16 to form the control gate electrodes 14 and 15 arranged to intersect with the fin-shaped stacked structures of the semiconductor layers 9 and the dielectric layers 11 via the charge storage layer 13 in the memory cell portion R1 and form the gate electrode 4, on the upper portion of which the control gate electrodes 14 and 15 electrically connected via the opening K1 is arranged, in the peripheral circuit portion R2. The half pitch of the control gate electrodes 14 and 15 of the memory cell portion R1 can be set to, for example, 22 nm.

Next, impurities are ion implanted in the semiconductor substrate 1 with the gate electrode 4, on the upper portion of which the control gate electrodes 14 and 15 are arranged, as a mask to form the LDD layer F1 arranged on both sides of the gate electrode 4 in the semiconductor substrate 1. It is applicable that the side walls of the gate electrode 4 and the control gate electrodes 14 and 15 thereon are oxidized by a rapid thermal oxidation that uses radicals generated from a hydrogen/oxygen mixed gas, and a polycrystalline silicon film that remains between the adjacent gate electrodes 4 and between the adjacent control gate electrodes 14 and 15 due to insufficient processing of the gate electrode 4 and the control gate electrodes 14 and 15 thereon is burned out, thereby preventing short circuits thereof and removing a process damage.

Next, as shown in FIG. 8, a dielectric film 17a filled between the control gate electrodes 14 and 15 of the memory cell portion R1 is formed and side walls 17b are formed on the side faces of the gate electrode 4 and the control gate electrodes 14 and 15 thereon of the peripheral circuit portion R2 by the ALD method.

Then, impurities are ion implanted in the semiconductor substrate 1 with the gate electrode 4, on the upper portion of which the control gate electrodes 14 and 15 are arranged, and the side walls 17b as a mask to form the high-concentration impurity diffusion layer F2 arranged on both sides of the gate electrode 4 via the LDD layer F1 in the semiconductor substrate 1.

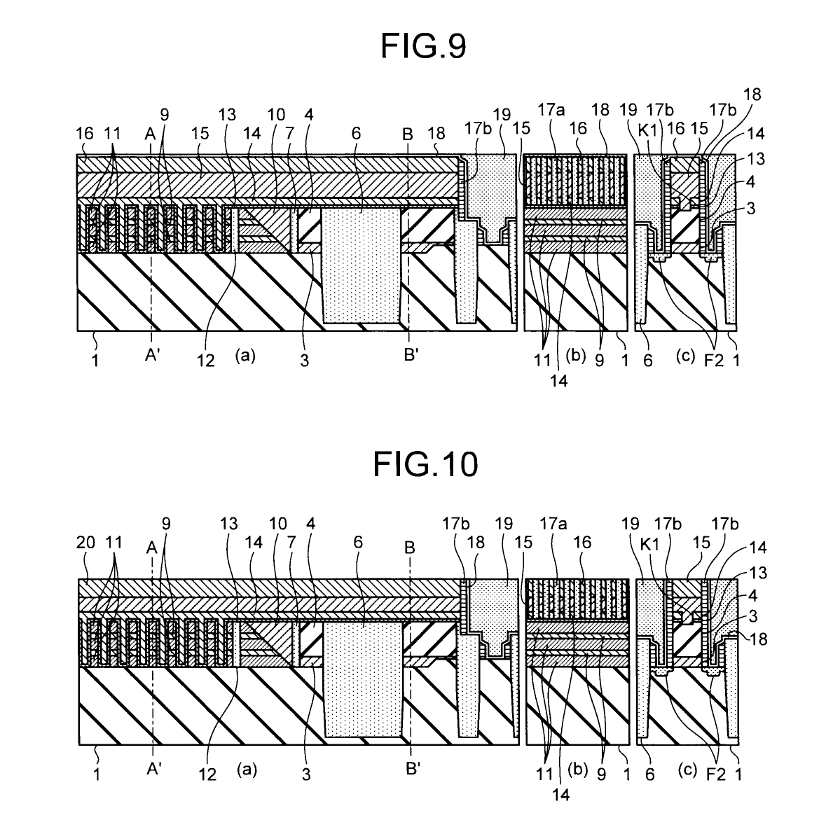

Next, as shown in FIG. 9, an oxidation barrier film 18 is formed on the hard mask film 16 by a method such as the CVD. As the oxidation barrier film 18, for example, a silicon nitride film can be used.

Next, a dielectric film 19 is formed on the oxidation barrier film 18 by a method such as the CVD so that the gate electrode 4 and the control gate electrodes 14 and 15 thereon of the peripheral circuit portion R2 are covered. As the dielectric film 19, for example, a BPSG film can be used. Alternatively, the dielectric film 19 can be melted in a steam oxidation atmosphere so that the gate electrode 4 and the control gate electrodes 14 and 15 thereon of the peripheral circuit portion R2 are completely filled. Then, the dielectric film 19 is polished by the CMP to planarize the dielectric film 19.

Next, as shown in FIG. 10, the dielectric film 19 is etched back and the hard mask film 16 and the oxidation barrier film 18 thereon are removed by the reactive ion etching to expose the control gate electrode 15. The etch-back amount of the dielectric film 19 can be set to, for example, 90 nm.

Next, a metal film is formed on the control gate electrode 15 by a method such as a sputtering. Then, the control gate electrode 15 is caused to react with the metal film by a method such as the RTA to form the silicide film 20 on the upper layer of the control gate electrode 15. Then, an unreacted metal film is removed by a method such as the wet etching. As the silicide film 20, for example, a nickel silicide film or a tungsten silicide film can be used. As a chemical for removing the unreacted metal film, the sulfuric acid/hydrogen peroxide mixture (SPM) can be used. In the following, a circuit of a flash memory is formed by a multilayer interconnection process.

According to the first embodiment, the stacked structure in which the dielectric layers 11 and the semiconductor layers 9 are alternately stacked can be processed into a fin shape by one lithography process, and the control gate electrodes 14 and 15 can be formed on both side surfaces of a plurality of layers of the semiconductor layers 9 by one lithography process. Therefore, a cell transistor having the Double Gate Fin Field Effect Transistor (DG-FinFET) can be formed over a plurality of layers while suppressing the number of processes, which is immune against the short channel effect since double gate electrodes controllability of channel is excellent, so that multi-level memory such as 2 bits/cell (=4 values) and 3 bits/cell (=8 values) can be realized easily and a memory bit density can be improved to double.

### Second Embodiment

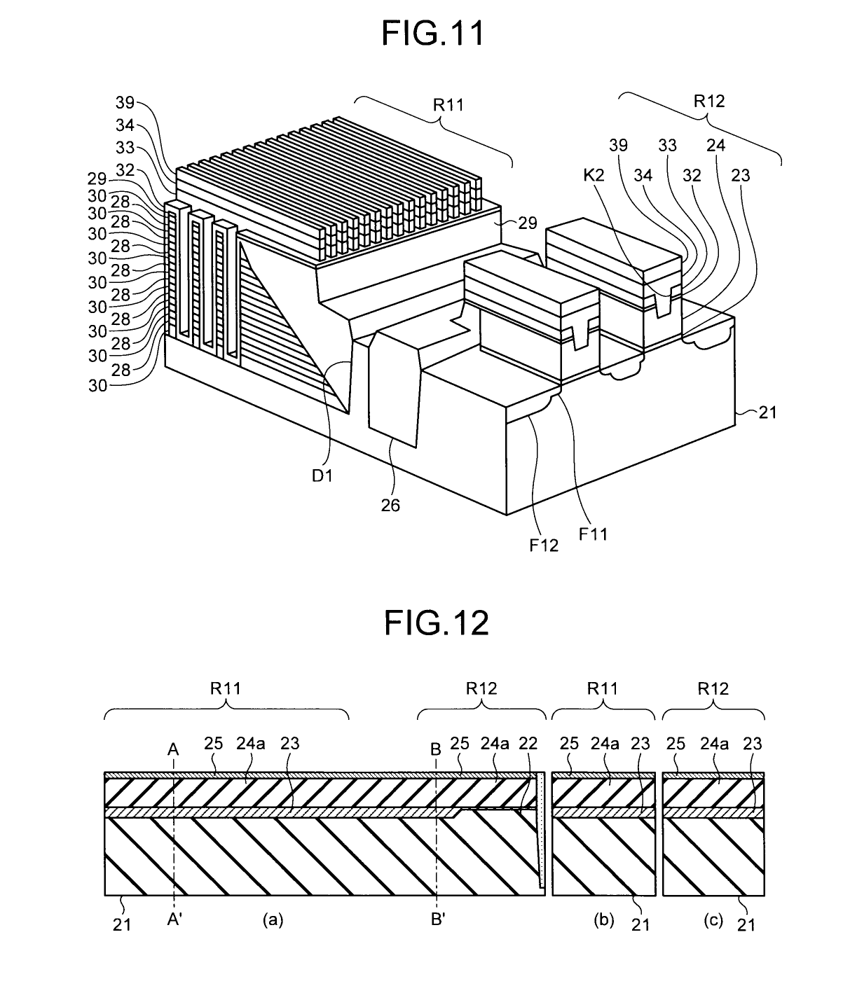

FIG. 11 is a perspective view illustrating a schematic configuration of a nonvolatile semiconductor storage device according to the second embodiment of the present invention.

In FIG. 11, a memory cell portion R11 and a peripheral circuit portion R12 are provided on a semiconductor substrate 21. A dielectric film 26 is filled in the semiconductor substrate 21 at a boundary between the memory cell portion R11 and the peripheral circuit portion R12. In the semiconductor substrate 21 of the memory cell portion R11, a step D1 that reduces a height difference between the memory cell portion R11 and the peripheral circuit portion R12 is formed.

In the memory cell portion R11, a stacked structure in which dielectric layers 30 and semiconductor layers 28 are alternately stacked is arranged in a fin shape on the bottom portion of the step D1 of the semiconductor substrate 21. Moreover, in the memory cell portion R11, control gate electrodes 33 and 34 are arranged to intersect with the fin-shaped stacked structures on a charge storage layer 32. The control gate electrodes 33 are arranged on the side surfaces of the semiconductor layers 28 via the charge storage layer 32 on the fin-shaped stacked structures, so that channel regions can be formed on the side surfaces of the semiconductor layers 28. A silicide film 39 is formed on the control gate electrode 34 of the memory cell portion R11.

On the other hand, in the peripheral circuit portion R12, a gate electrode 24 is arranged on the semiconductor substrate 21 via a gate dielectric film 23. The charge storage layer 32, the control gate electrodes 33 and 34, and the silicide film 39 are stacked in order on the gate electrode 24. An opening K2 is formed in the charge storage layer 32 and the control gate electrode 33 to expose the gate electrode 24. The control gate electrode 34 of the peripheral circuit portion R12 is connected to the gate electrode 24 via the opening K2. In the semiconductor substrate 21 of the peripheral circuit portion R12, a high-concentration impurity diffusion layer F12 arranged on both sides of the gate electrode 24 via an LDD layer F11 is formed.

The height of the upper surface of the gate electrode 24 on the semiconductor substrate 21 can be set to be substantially equal to the height of the upper surface of the stacked structure in which the dielectric layers 30 and the semiconductor layers 28 are alternately stacked.

With this structure, even when the dielectric layers 30 and the semiconductor layers 28 are alternately stacked on the semiconductor substrate 21, the step between the memory cell portion R11 and the peripheral circuit portion R12 can be reduced without increasing the height of the gate electrode 24. Therefore, a contact hole connected to the high-concentration impurity diffusion layer F12 can be formed easily and a contact plug can be filled easily even when a circuit of a flash memory is formed by a multilayer interconnection process.

FIG. 12A to FIG. 19A are cross-sectional views illustrating a manufacturing method of the nonvolatile semiconductor storage device shown in FIG. 11, FIG. 12B to FIG. 19B are cross-sectional views taken along lines A-A′ in FIG. 12A to FIG. 19A, respectively, and FIG. 12C to FIG. 19C are cross-sectional views taken along lines B-B′ in FIG. 12A to FIG. 19A, respectively. In this manufacturing method, a flash memory is taken as an example, which realizes a cell area of 472 nm² that is equivalent to hp 11 nm generation in a planar cell structure by stacking eight layers of a memory cell designed such that the half pitch of the bit line is 43 nm and the half pitch of the word line is 22 nm.

In FIG. 12, a recess is formed in the memory cell portion R11 and the peripheral circuit portion R12 on the semiconductor substrate 21 by the lithography technique and the reactive ion etching technique. The depth of the recess can be set to, for example, about 25 nm.

Next, the gate dielectric film 23 is formed on the semiconductor substrate 21 by performing the thermal oxidation on the semiconductor substrate 21. Then, the gate dielectric film 23 of the low voltage circuit portion of the peripheral circuit portion R12 is removed by the lithography technique and the wet etching technology. Then, a gate dielectric film 22 is formed on the semiconductor substrate 21 of the low voltage circuit portion of the peripheral circuit portion R12 by performing the thermal oxidation on the semiconductor substrate 21. As the gate dielectric films 22 and 23, for example, a silicon thermally-oxidized film can be used. The film thickness of the gate dielectric film 22 can be set to, for example, about 6 nm. The film thickness of the gate dielectric film 23 after forming the gate dielectric film 22 can be set to, for example, about 40 nm.

Next, a gate electrode film 24a is formed on the gate dielectric films 22 and 23 by a method such as the CVD. As the gate electrode film 24a, for example, an n-type polycrystalline silicon film can be used. The film thickness of the gate electrode film 24a can be set to, for example, about 110 nm.

Next, a CMP stopper film 25 is formed on the gate electrode film 24a by a method such as the CVD. As the CMP stopper film 25, for example, a silicon nitride film can be used. The film thickness of the CMP stopper film 25 can be set to, for example, about 30 nm.

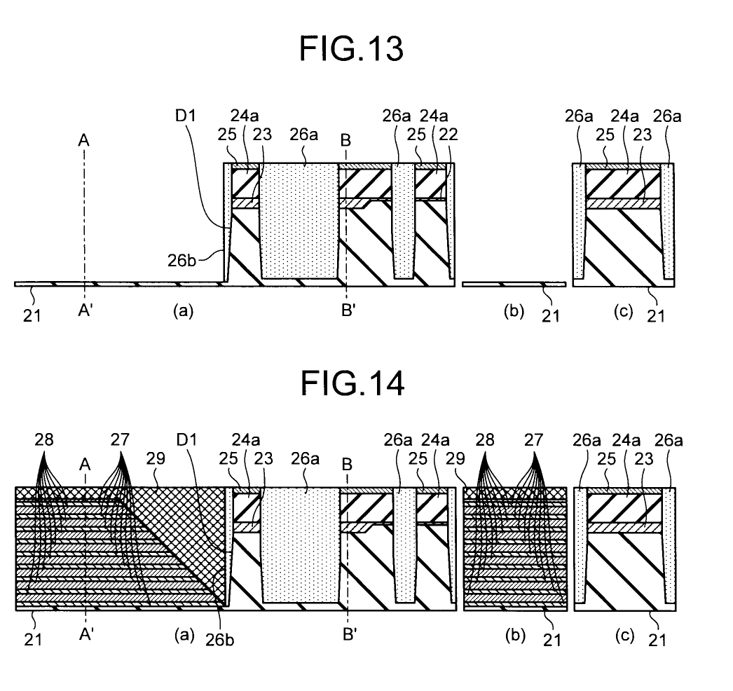

Next, as shown in FIG. 13, an isolation trench is formed in the CMP stopper film 25, the gate electrode film 24a, the gate dielectric film 22 and 23, the semiconductor substrate 21, and a step D1 is formed on the semiconductor substrate 21 of the memory cell portion R21, by the lithography technique and the reactive ion etching technique. Then, a dielectric film is stacked on the semiconductor substrate 21 by a method such as the CVD so that the isolation trench and the step D1 are filled. Then, a dielectric film 26a filled in the isolation trench is formed and the dielectric film filled in the step D1 is planarized by polishing the dielectric film by the CMP until the CMP stopper film 25 is exposed. Then, the dielectric film filled in the step D1 is selectively etched back by the lithography technique and the reactive ion etching technique to form a side wall 26b on the side facel of the step D1. As the dielectric film 26a and the side wall 26b, for example, a high density plasma enhanced CVD SiO₂ (HDP-CVD SiO₂) film or a TEOS-O₃ film can be used.

Next, as shown in FIG. 14, the clean surface of the semiconductor substrate 21 is exposed by the dilute hydrofluoric acid treatment. Then, semiconductor layers 27 and 28 are selectively epitaxially grown alternately on the bottom portion of the step D1 of the semiconductor substrate 21 by the LPCVD method. A monocrystalline semiconductor layer can be formed only in the memory cell portion R11 by performing the selective epitaxial growth. When the semiconductor substrate 21 is Si, it is preferable to use SiGe for the semiconductor layer 27 and Si for the semiconductor layer 28. The film thickness of the semiconductor layers 27 and 28 can be set to, for example, 20 nm, 45 nm, 20 nm, 45 nm, 20 nm, 45 nm, 20 nm, 45 nm, 20 nm, 45 nm, 20 nm, 45 nm, 20 nm, 45 nm, 20 nm, 45 nm, 20 nm, and 10 nm in order from the bottom. The connection of each layer of the semiconductor layers 28 to the peripheral circuit can be controlled independently by forming an impurity diffusion layer, in which impurities are locally doped, at a different location for each layer of the stacked semiconductor layers 28. For example, impurities can be doped by the ion implantation.

Next, a planarization film 29 is formed on the semiconductor substrate 21 by a method such as the CVD. Then, the planarization film 29 is polished by a method such as the CVD until the CMP stopper film 25 is exposed to planarize the memory cell portion R11.

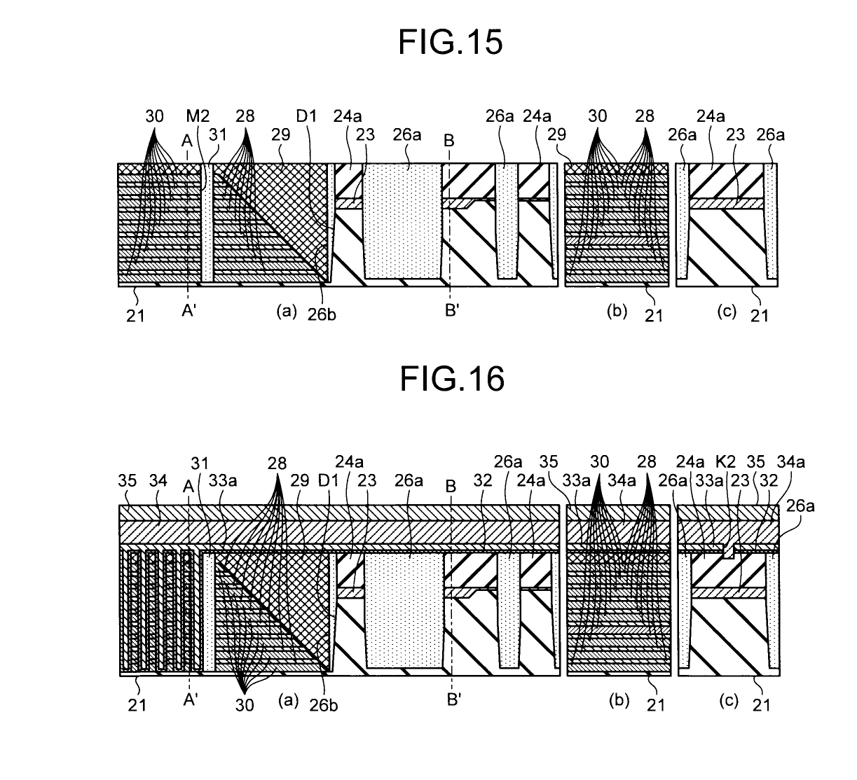

Next, as shown in FIG. 15, trenches M2 are formed in the stacked structure of the semiconductor layers 27 and 28 by the lithography technique and the reactive ion etching technique to expose the side walls of the semiconductor layers 27 and 28 at predetermined intervals. Then, the semiconductor layers 27 are selectively removed by the wet etching to form a space between the semiconductor layers 28. For example, a mixture of hydrofluoric acid/nitric acid/acetic acid can be used as a chemical for the wet etching. Alternatively, the semiconductor layers 27 can be selectively removed by the chemical dry etching. Still alternatively, the semiconductor layers 27 can be selectively removed by a gas etching with chlorine gas.

Next, the dielectric layers 30 filled between the semiconductor layers 28 are formed by performing the steam oxidation on the upper and lower surfaces of the semiconductor layers 28 via the trenches M2. As the dielectric layer 30, for example, a silicon thermally-oxidized film can be used. As a method for forming the dielectric layers 30 filled between the semiconductor layers 28, the CVD method or the ALD method can be used other than the steam oxidation of the semiconductor layers 28. Alternatively, an SOG film can be filled by a coating method, or a liquid organic dielectric film can be injected into the space between the semiconductor layers 28 and then cured.

Next, a dielectric film 31 filled in the trenches M2 is formed by a method such as the CVD. As the dielectric film 31, for example, a silicon oxide film can be used. Then, the dielectric film 31 and the CMP stopper film 25 are etched back by the reactive ion etching to expose the gate electrode film 24a of the peripheral circuit portion R12.

Next, as shown in FIG. 16, the stacked structure of the semiconductor layers 28 and the dielectric layers 30 is processed into a fin shape by the lithography technique and the reactive ion etching to expose the side surfaces of the semiconductor layers 28. The width of this fin-shaped structure can be set to, for example, 30 nm. The half pitch of this fin-shaped structure can be set to, for example, 43 nm.

Next, after performing a pretreatment with dilute hydrofluoric acid, the charge storage layer 32 is formed on the stacked structure of the semiconductor layers 28 and the dielectric layers 30 and the gate electrode film 24a by a method such as the CVD so that the side surfaces of the semiconductor layers 28 are covered. As the charge storage layer 32, for example, the ANO structure formed of the aluminum oxide film/silicon nitride film/silicon oxide film can be used, and the film thickness at this time can be set to, for example, 13 nm, 2 nm, and 3 nm in order from the bottom.

Next, a control gate electrode film 33a is formed on the charge storage layer 32 by a method such as the CVD. As the control gate electrode film 33a, for example, an n-type polycrystalline silicon film can be used. The thickness of the control gate electrode film 33a can be set to, for example, about 40 nm.

Next, the opening K2 that exposes the gate electrode film 24a of the peripheral circuit portion R12 is formed in the charge storage layer 32 and the control gate electrode film 33a by the lithography technique and the reactive ion etching.

Next, a control gate electrode film 34a connected to the gate electrode film 24a via the opening K2 is formed on the control gate electrode film 33a by a method such as the CVD. As the control gate electrode film 34a, for example, an n-type polycrystalline silicon film can be used. The thickness of the control gate electrode film 34a can be set to, for example, about 150 nm.

Next, a hard mask film 35 is formed on the control gate electrode film 34a by a method such as the CVD. As the hard mask film 35, for example, a silicon nitride film can be used. The thickness of the hard mask film 35 can be set to, for example, about 100 nm.

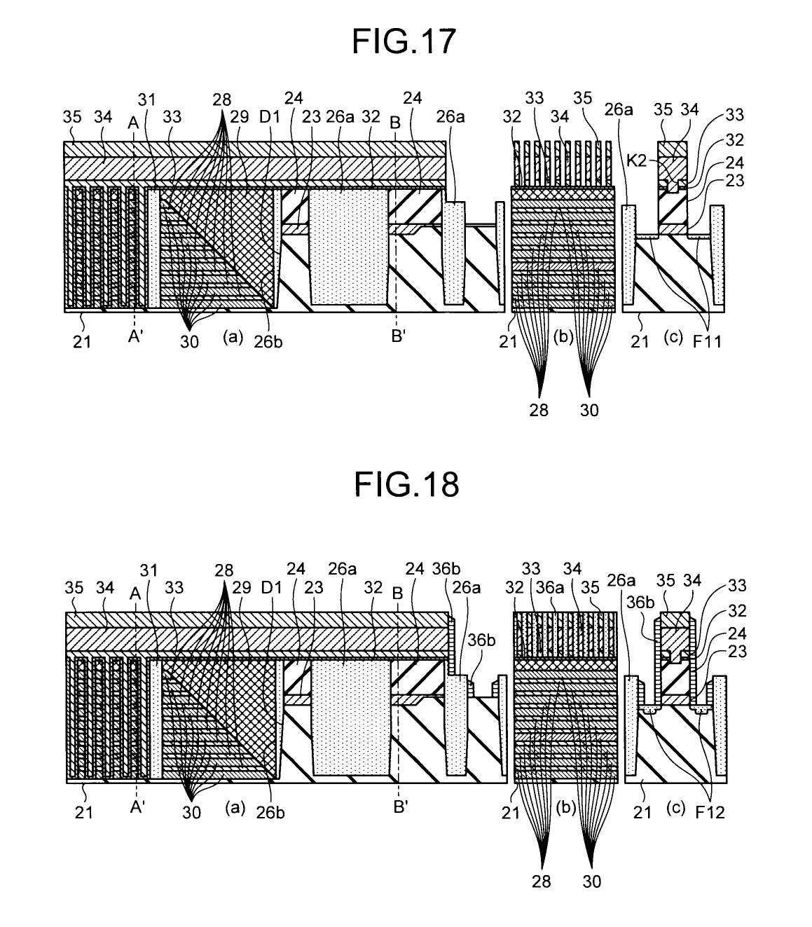

Next, as shown in FIG. 17, a patterning is performed on the hard mask film 35 to correspond to the planar shape of the gate electrode 24 and the control gate electrodes 33 and 34 by the lithography technique and the reactive ion etching technique. Then, the reactive ion etching of the control gate electrode films 34a and 33a, the charge storage layer 32, and the gate electrode film 24a is collectively performed via the hard mask film 35 to form the control gate electrodes 33 and 34 arranged to intersect with the fin-shaped stacked structures of the semiconductor layers 28 and the dielectric layers 30 via the charge storage layer 32 in the memory cell portion R11 and form the gate electrode 24, on the upper portion of which the control gate electrodes 33 and 34 electrically connected via the opening K2 is arranged, in the peripheral circuit portion R12. The half pitch of the control gate electrodes 33 and 34 of the memory cell portion R11 can be set to, for example, 22 nm.

Next, impurities are ion implanted in the semiconductor substrate 21 with the gate electrode 24, on the upper portion of which the control gate electrodes 33 and 34 are arranged, as a mask to form the LDD layer F11 arranged on both sides of the gate electrode 24 in the semiconductor substrate 21. It is applicable that the side faces of the gate electrode 24 and the control gate electrodes 33 and 34 thereon are oxidized by the rapid thermal oxidation that uses radicals generated from a hydrogen/oxygen mixed gas, and a polycrystalline silicon film that remains between the adjacent gate electrodes 24 and between the adjacent control gate electrodes 33 and 34 due to insufficient processing of the gate electrode 24 and the control gate electrodes 33 and 34 thereon is burned out, thereby preventing short circuits thereof and removing a process damage.

Next, as shown in FIG. 18, a dielectric film 36a filled between the control gate electrodes 33 and 34 of the memory cell portion R11 is formed and side walls 36b are formed on the side faces of the gate electrode 24 and the control gate electrodes 33 and 34 thereon of the peripheral circuit portion R12 by the ALD method.

Then, impurities are ion implanted in the semiconductor substrate 21 with the gate electrode 24, on the upper portion of which the control gate electrodes 33 and 34 are arranged, and the side walls 36b as a mask to form the high-concentration impurity diffusion layer F12 arranged on both sides of the gate electrode 24 via the LDD layer F11 in the semiconductor substrate 21.

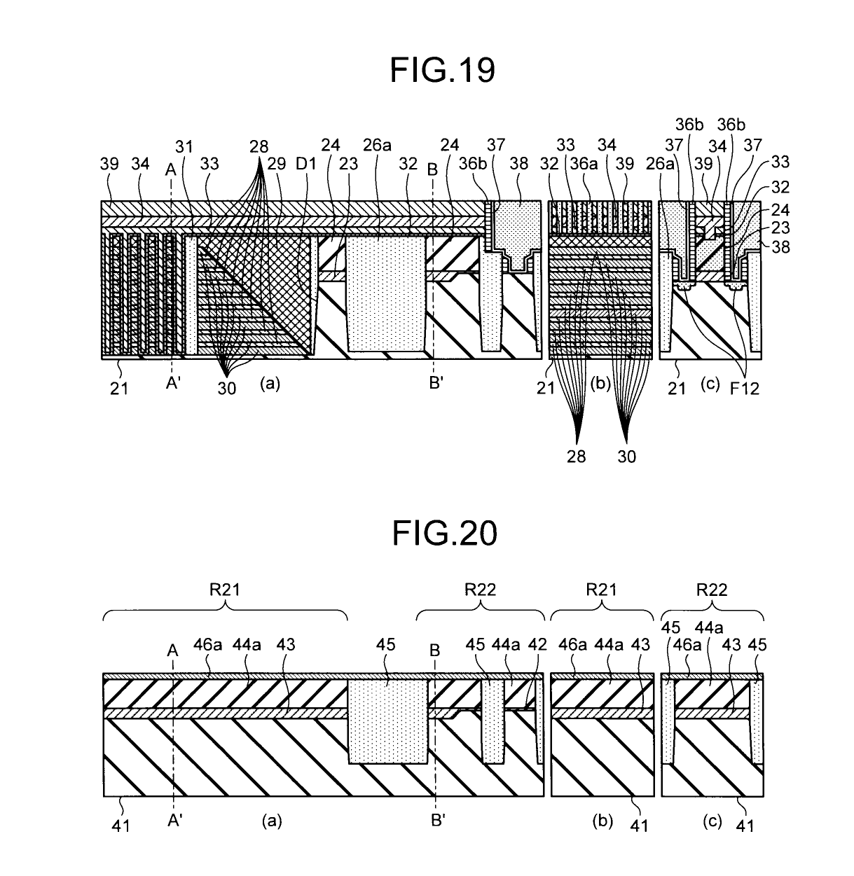

Next, as shown in FIG. 19, an oxidation barrier film 37 is formed by a method such as the CVD. As the oxidation barrier film 37, for example, a silicon nitride film can be used.

Next, a dielectric film 38 is formed on the oxidation barrier film 37 by a method such as the CVD so that the gate electrode 24 and the control gate electrodes 33 and 34 thereon of the peripheral circuit portion R12 are covered. As the dielectric film 38, for example, a BPSG film can be used. Alternatively, the dielectric film 38 can be melted in a steam oxidation atmosphere so that the gate electrode 24 and the control gate electrodes 33 and 34 thereon of the peripheral circuit portion R12 are completely filled. Then, the dielectric film 38 is polished by the CMP to planarize the dielectric film 38.

Next, the dielectric film 38 is etched back and the hard mask film 35 and the oxidation barrier film 37 thereon are removed by the reactive ion etching to expose the control gate electrode 34. The etch-back amount of the dielectric film 38 can be set to, for example, 90 nm.

Next, a metal film is formed on the control gate electrode 34 by a method such as the sputtering. Then, the control gate electrode 34 is caused to react with the metal film by a method such as the RTA to form the silicide film 39 on the upper layer of the control gate electrode 34. Then, an unreacted metal film is removed by a method such as the wet etching. As the silicide film 39, for example, a nickel silicide film or a tungsten silicide film can be used. As a chemical for removing the unreacted metal film, the sulfuric acid/hydrogen peroxide mixture (SPM) can be used. In the following, a circuit of a flash memory is formed by the multilayer interconnection process.

According to the second embodiment, even when the number of the the semiconductor layers 28 is large, the stacked structure in which the dielectric layers 30 and the semiconductor layers 28 are alternately stacked can be processed into a fin shape by only one lithography process, and the control gate electrodes 33 and 34 can be formed on both side surfaces of a plurality of layers of the semiconductor layers 28 by one lithography process. Therefore, a cell transistor having the DG-FinFET can be formed over a plurality of layers while suppressing the number of processes, which is insensitive to a short channel effect since gate electrodes of DG-FinFET control a channel strongly, so that multi-level memory such as 2 bits/cell (=4 values) and 3 bits/cell (=8 values) can be realized easily and a memory density can be improved to eight times.

### Third Embodiment

FIG. 20A to FIG. 26A are cross-sectional views illustrating a manufacturing method of a nonvolatile semiconductor storage device according to the third embodiment of the present invention, FIG. 20B to FIG. 26B are cross-sectional views taken along lines A-A′ in FIG. 20A to FIG. 26A, respectively, and FIG. 20C to FIG. 26C are cross-sectional views taken along lines B-B′ in FIG. 20A to FIG. 26A, respectively. In this manufacturing method, a flash memory is taken as an example, which realizes a cell area of 144 nm² that is equivalent to hp 8 nm generation in a planar cell structure by stacking eight layers of a memory cell designed such that the half pitch of the bit line is 24 nm and the half pitch of the word line is 24 nm.

In FIG. 20, a recess is formed in a memory cell portion R21 and a peripheral circuit portion R22 on a semiconductor substrate 41 by the lithography technique and the reactive ion etching technique. The depth of the recess can be set to, for example, about 25 nm.

Next, a gate dielectric film 43 is formed on the semiconductor substrate 41 by performing the thermal oxidation on the semiconductor substrate 41. Then, the gate dielectric film 43 of the low voltage circuit portion of the peripheral circuit portion R22 is removed by the lithography technique and the wet etching technology. Then, a gate dielectric film 42 is formed on the semiconductor substrate 41 of the low voltage circuit portion of the peripheral circuit portion R22 by performing the thermal oxidation on the semiconductor substrate 41. As the gate dielectric films 42 and 43, for example, a silicon thermally-oxidized film can be used. The film thickness of the gate dielectric film 42 can be set to, for example, about 6 nm. The film thickness of the gate dielectric film 43 after forming the gate dielectric film 42 can be set to, for example, about 40 nm.

Next, a gate electrode film 44a is formed on the gate dielectric films 42 and 43 by a method such as the CVD. As the gate electrode film 44a, for example, an n-type polycrystalline silicon film can be used. The film thickness of the gate electrode film 44a can be set to, for example, about 60 nm.

Next, an isolation trench is formed in the gate electrode film 44a, the gate dielectric films 42 and 43, and the semiconductor substrate 41 by the lithography technique and the reactive ion etching technique. Then, a dielectric film 45 filled in the isolation trench is formed by a method such as the CVD. Then, the dielectric film 45 is planarized by the CMP with the gate electrode film 44a as a CMP stopper film to form the STI structure that isolates the peripheral circuit portion R22 on the semiconductor substrate 41. As the dielectric film 45, for example, a high density plasma enhanced CVD SiO₂ (HDP-CVD SiO₂) film or a TEOS-O₃ film can be used.

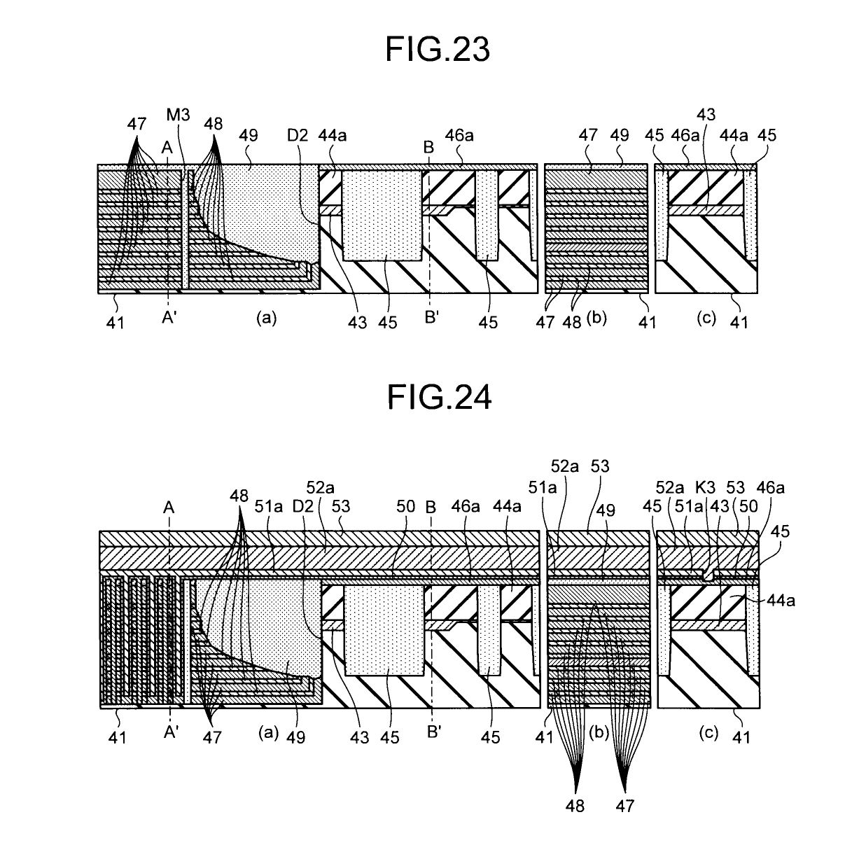

Next, a gate electrode film 46a is formed on the gate electrode film 44a by a method such as the CVD. As the gate electrode film 46a, for example, an n-type polycrystalline silicon film can be used. The film thickness of the gate electrode film 46a is preferably set such that the height of the upper surface of the gate electrode film 46a shown in FIG. 23 substantially corresponds to the height of the upper surface of the stacked structure of dielectric layers 47 and semiconductor layers 48.

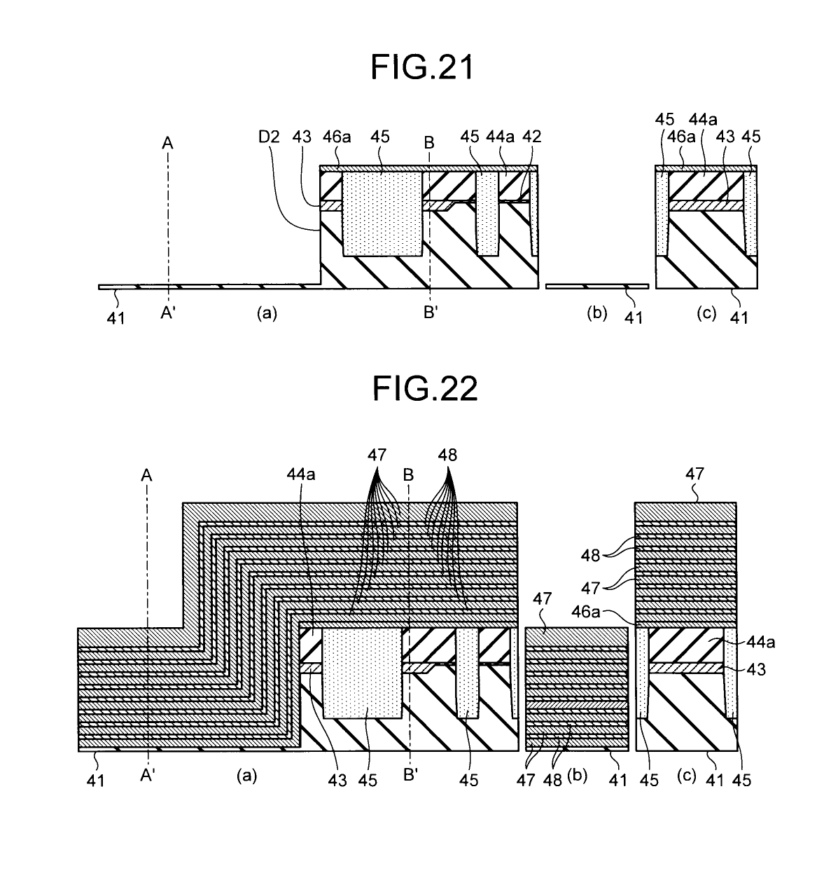

Next, as shown in FIG. 21, the gate electrode films 46a and 44a and the gate dielectric film 43 of the memory cell portion R21 are removed and the semiconductor substrate 41 is etched to form a step D2 on the semiconductor substrate 41 of the memory cell portion R21 by the lithography technique and the reactive ion etching technique.

Next, as shown in FIG. 22, the clean surface of the semiconductor substrate 41 is exposed by the dilute hydrofluoric acid treatment. Then, the dielectric layers 47 and the semiconductor layers 48 are alternately stacked so that the bottom portion of the step D2 of the semiconductor substrate 41 is filled and one dielectric layer 47 is further stacked thereon, by the LPCVD method. For example, a TEOS film can be used as the dielectric layer 47 and a polycrystalline silicon film can be used as the semiconductor layer 48. The thickness of one dielectric layer 47 can be set to, for example, 30 nm, and the thickness of one semiconductor layer 48 can be set to, for example, 20 nm. The thickness of the uppermost dielectric layer 47 can be set to, for example, 50 nm. The connection of each layer of the semiconductor layers 48 to the peripheral circuit can be controlled independently by forming an impurity diffusion layer, in which impurities are locally doped, at a different location for each layer of the stacked semiconductor layers 48.

Next, as shown in FIG. 23, the dielectric layers 47 and the semiconductor layers 48 of the peripheral circuit portion R22 are removed by the lithography technique and the reactive ion etching technique to expose the gate electrode film 46a of the peripheral circuit portion R22. Next, a trench M3 that surrounds the memory cell portion R21 is formed by the lithography technique and the reactive ion etching technique. The formation of the trench M3 can be skipped.

Next, a planarization film 49 is formed on the semiconductor substrate 41 by a method such as the CVD. Then, the planarization film 49 is polished by a method such as the CMP with the gate electrode film 46a as a CMP stopper film to planarize the memory cell portion R21. As the planarization film 49, for example, a Non-doped Silicate Glass (NSG) film can be used.

Next, as shown in FIG. 24, the stacked structure of the semiconductor layers 48 and the dielectric layers 47 is processed into a fin shape by the lithography technique and the reactive ion etching to expose the side surfaces of the semiconductor layers 48. The interval of the fins can be set to, for example, 20 nm, and the width of this fin-shaped structure can be set to, for example, 15 nm. The half pitch of this fin-shaped structure can be set to, for example, 24 nm.

Next, after performing a pretreatment with dilute hydrofluoric acid, a charge storage layer 50 is formed on the stacked structure of the semiconductor layers 48 and the dielectric layers 47 and the gate electrode film 46a by a method such as the CVD so that the side surfaces of the semiconductor layers 48 are covered. As the charge storage layer 50, for example, the ONO structure formed of the silicon oxide film/silicon nitride film/silicon oxide film can be used, and the film thickness at this time can be set to, for example, 3 nm, 2 nm, and 7 nm in order from the bottom.

Next, a control gate electrode film 51a is formed on the charge storage layer 50 by a method such as the CVD. As the control gate electrode film 51a, for example, an n-type polycrystalline silicon film can be used. The thickness of the control gate electrode film 51a can be set to, for example, about 40 nm.

Next, an opening K3 that exposes the gate electrode film 46a of the peripheral circuit portion R22 is formed in the charge storage layer 50 and the control gate electrode film 51a by the lithography technique and the reactive ion etching.

Next, a control gate electrode film 52a connected to the gate electrode film 46a via the opening K3 is formed on the control gate electrode film 51a by a method such as the CVD. As the control gate electrode film 52a, for example, an n-type polycrystalline silicon film can be used. The thickness of the control gate electrode film 52a can be set to, for example, about 150 nm.

Next, a hard mask film 53 is formed on the control gate electrode film 52a by a method such as the CVD. As the hard mask film 53, for example, a silicon nitride film can be used. The thickness of the hard mask film 53 can be set to, for example, about 100 nm.

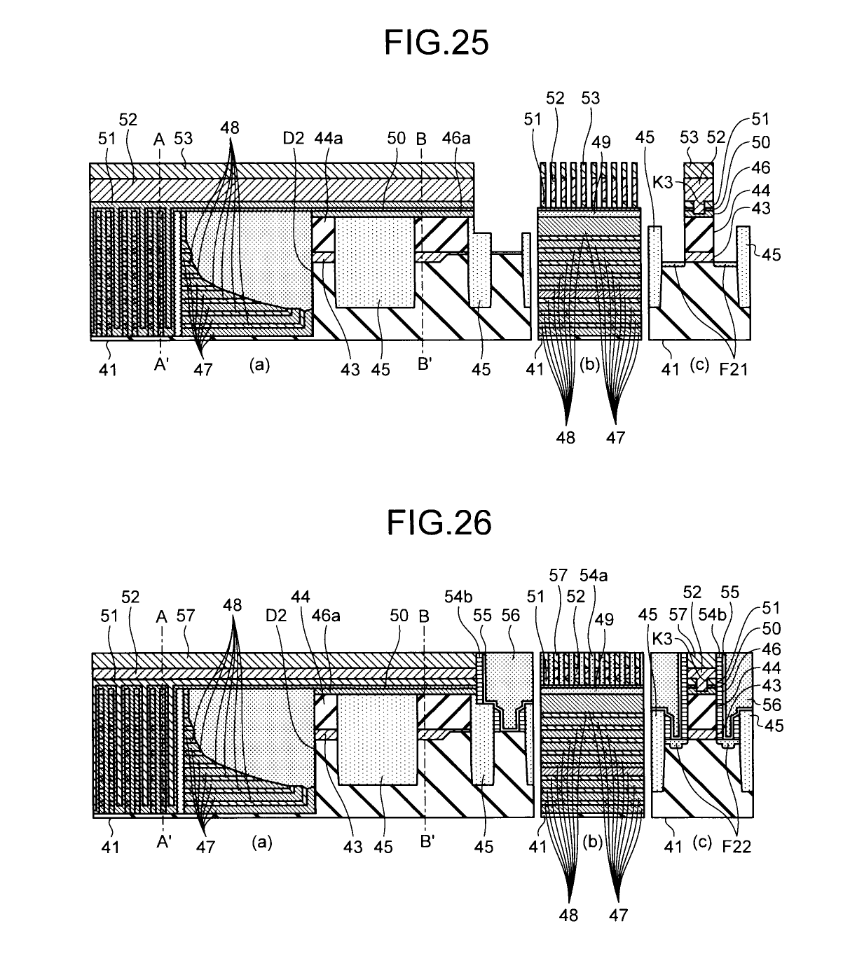

Next, as shown in FIG. 25, a patterning is performed on the hard mask film 53 to correspond to the planar shape of gate electrodes 44 and 46 and control gate electrodes 51 and 52 by the lithography technique and the reactive ion etching technique. Then, the reactive ion etching of the control gate electrode films 52a and 51a, the charge storage layer 50, and the gate electrode films 46a and 44a is collectively performed via the hard mask film 53 to form the control gate electrodes 51 and 52 arranged to intersect with the fin-shaped stacked structures of the semiconductor layers 48 and the dielectric layers 47 via the charge storage layer 50 in the memory cell portion R21 and form the gate stacked structure composed of the gate electrode 46, on the upper portion of which the control gate electrodes 51 and 52 electrically connected via the opening K3 is arranged, and the gate electrode 44 therebelow in the peripheral circuit portion R22. The half pitch of the control gate electrodes 51 and 52 of the memory cell portion R21 can be set to, for example, 24 nm.

Next, impurities are ion implanted in the semiconductor substrate 41 with the gate electrodes 44 and 46, on the upper portion of which the control gate electrodes 51 and 52 are arranged, as a mask to form an LDD layer F21 arranged on both sides of the gate electrodes 44 and 46 in the semiconductor substrate 41. It is applicable that the side faces of the gate electrodes 44 and 46 and the control gate electrodes 51 and 52 are oxidized by the rapid thermal oxidation that uses radicals generated from a hydrogen/oxygen mixed gas, and a polycrystalline silicon film that remains between the adjacent gate electrodes 44 and 46 and between the adjacent control gate electrodes 51 and 52 due to insufficient processing of the gate electrodes 44 and 46 and the control gate electrodes 51 and 52 is burned out, thereby preventing short circuits thereof and removing a process damage. The temperature for this radical oxidation can be set to, for example, 400° C.

Next, as shown in FIG. 26, a dielectric film 54a filled between the control gate electrodes 51 and 52 of the memory cell portion R21 is formed and side walls 54b are formed on the side faces of the gate electrodes 44 and 46 and the control gate electrodes 51 and 52 of the peripheral circuit portion R22 by the ALD method. As the dielectric film 54a and the side wall 54b, for example, an NSG film can be used.

Then, impurities are ion implanted in the semiconductor substrate 41 with the gate electrodes 44 and 46, on the upper portion of which the control gate electrodes 51 and 52 are arranged, and the side walls 54b as a mask to form a high-concentration impurity diffusion layer F22 arranged on both sides of the gate electrodes 44 and 46 via the LDD layer F21 in the semiconductor substrate 41.

Next, an oxidation barrier film 55 is formed by a method such as the CVD. As the oxidation barrier film 55, for example, a silicon nitride film can be used.

Next, a dielectric film 56 is formed on the oxidation barrier film 55 by a method such as the CVD so that the gate electrodes 44 and 46 and the control gate electrodes 51 and 52 of the peripheral circuit portion R22 are filled. As the dielectric film 56, for example, a BPSG film can be used. Alternatively, the dielectric film 56 can be melted in a steam oxidation atmosphere so that the gate electrodes 44 and 46 and the control gate electrodes 51 and 52 of the peripheral circuit portion R22 are completely covered. Then, the dielectric film 56 is polished by the CMP to planarize the dielectric film 56.

Next, the dielectric film 56 is etched back and the hard mask film 53 and the oxidation barrier film 55 thereon are removed by the reactive ion etching to expose the control gate electrode 52. The etch-back amount of the dielectric film 56 can be set to, for example, 90 nm.

Next, a metal film is formed on the control gate electrode 52 by a method such as the sputtering. Then, the control gate electrode 52 is caused to react with the metal film by a method such as the RTA to form a silicide film 57 on the upper layer of the control gate electrode 52. Then, an unreacted metal film is removed by a method such as the wet etching. As the silicide film 57, for example, a nickel silicide film or a tungsten silicide film can be used. As a chemical for removing the unreacted metal film, the sulfuric acid/hydrogen peroxide mixture (SPM) can be used. In the following, a circuit of a flash memory is formed by the multilayer interconnection process.

According to the third embodiment, even when the number of the the semiconductor layers 48 is large, the stacked structure in which the dielectric layers 47 and the semiconductor layers 48 are alternately stacked can be processed into a fin shape by one lithography process, and the control gate electrodes 51 and 52 can be formed on both side surfaces of a plurality of layers of the semiconductor layers 48 by one lithography process. Therefore, a cell transistor having an ultra thin silicon on insulator (UTSOI) structure can be formed over a plurality of layers while suppressing the number of processes, which is immune against a short channel effect since the gate electrode of UTSOI strongly dominates its channel, so that multi-level memory such as 2 bits/cell (=4 values) and 3 bits/cell (=8 values) can be realized easily and a memory density can be improved to eight times.

### Fourth Embodiment

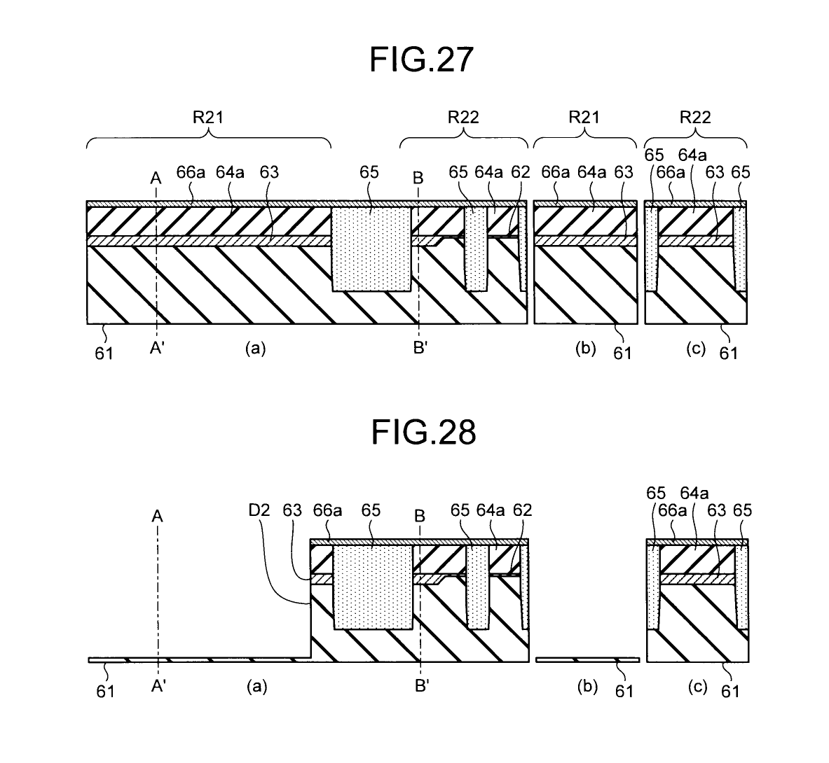

FIG. 27A to FIG. 33A are cross-sectional views illustrating a manufacturing method of a nonvolatile semiconductor storage device according to the fourth embodiment of the present invention, FIG. 27B to FIG. 33B are cross-sectional views taken along lines A-A′ in FIG. 27A to FIG. 33A, respectively, and FIG. 27C to FIG. 33C are cross-sectional views taken along lines B-B′ in FIG. 27A to FIG. 33A, respectively. In this manufacturing method, a flash memory is taken as an example, which realizes a cell area of 144 nm² that is equivalent to hp 8 nm generation in a planar cell structure by stacking eight layers of a memory cell designed such that the half pitch of the bit line is 24 nm and the half pitch of the word line is 24 nm.

In FIG. 27, a recess is formed in the memory cell portion R21 and the peripheral circuit portion R22 on a semiconductor substrate 61 by the lithography technique and the reactive ion etching technique. The depth of the recess can be set to, for example, about 25 nm.

Next, a gate dielectric film 63 is formed on the semiconductor substrate 61 by performing the thermal oxidation on the semiconductor substrate 61. Then, the gate dielectric film 63 of the low voltage circuit portion of the peripheral circuit portion R22 is removed by the lithography technique and the wet etching technology. Then, a gate dielectric film 62 is formed on the semiconductor substrate 61 of the low voltage circuit portion of the peripheral circuit portion R22 by performing the thermal oxidation on the semiconductor substrate 61. As the gate dielectric films 62 and 63, for example, a silicon thermally-oxidized film can be used. The film thickness of the gate dielectric film 62 can be set to, for example, about 6 nm. The film thickness of the gate dielectric film 63 after forming the gate dielectric film 62 can be set to, for example, about 40 nm.

Next, a gate electrode film 64a is formed on the gate dielectric films 62 and 63 by a method such as the CVD. As the gate electrode film 64a, for example, an n-type polycrystalline silicon film can be used. The film thickness of the gate electrode film 64a can be set to, for example, about 60 nm.

Next, an isolation trench is formed in the gate electrode film 64a, the gate dielectric film 62 and 63, and the semiconductor substrate 61 by the lithography technique and the reactive ion etching technique. Then, a dielectric film 65 filled in the isolation trench is formed by a method such as the CVD. Then, the dielectric film 65 is polished by the CMP with the gate electrode film 64a as a CMP stopper film to form the STI structure that isolates the peripheral circuit portion R22 on the semiconductor substrate 61. As the dielectric film 65, for example, a high density plasma enhanced CVD SiO₂ (HDP-CVD SiO₂) film or a TEOS-O₃ film can be used.

Next, a gate electrode film 66a is formed on the gate electrode film 64a by a method such as the CVD. As the gate electrode film 66a, for example, an n-type polycrystalline silicon film can be used. The film thickness of the gate electrode film 66a is preferably set such that the height of the upper surface of the gate electrode film 66a shown in FIG. 30 substantially corresponds to the height of the upper surface of the laminated structure of first semiconductor layers 67, second semiconductor layers 68, and a dielectric layer 69.

Next, as shown in FIG. 28, the gate electrode films 66a and 64a and the gate dielectric film 63 of the memory cell portion R21 are removed and the semiconductor substrate 61 is etched to form the step D2 on the semiconductor substrate 61 of the memory cell portion R21 by the lithography technique and the reactive ion etching technique.

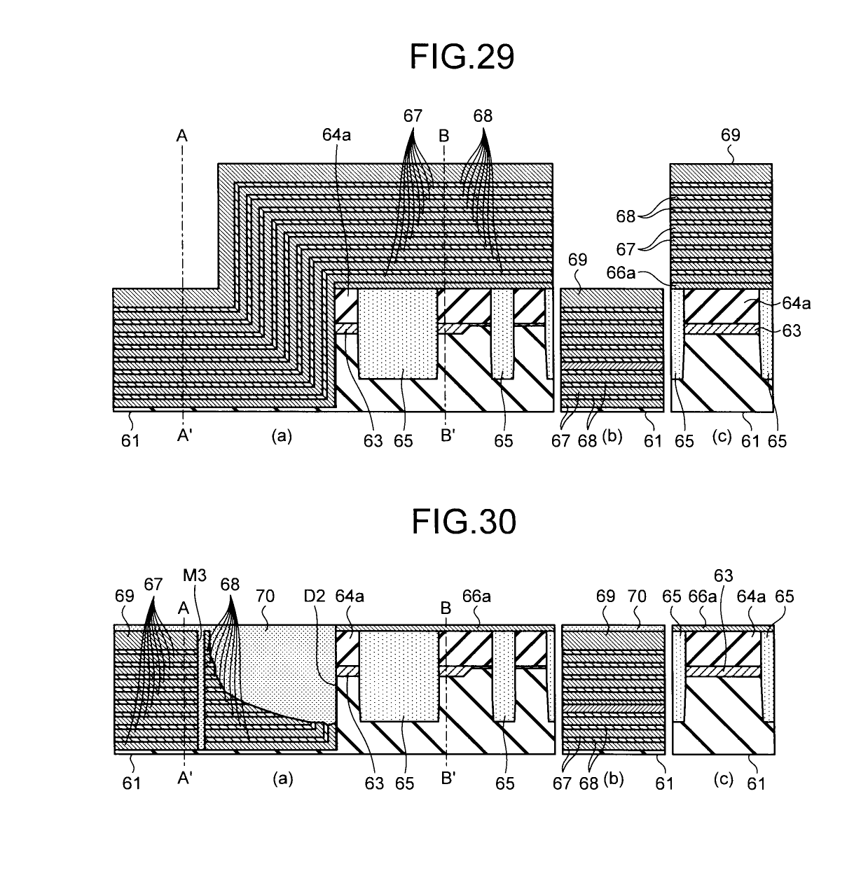

Next, as shown in FIG. 29, the clean surface of the semiconductor substrate 61 is exposed by the dilute hydrofluoric acid treatment. Then, the first semiconductor layers 67 and the second semiconductor layers 68 are alternately stacked so that the bottom portion of the step D2 of the semiconductor substrate 61 is filled, and one dielectric layer 69 is further stacked thereon, by the LPCVD method. Preferably, SiGe is used as the semiconductor layer 67 and Si is used as the semiconductor layer 68. The thickness of one semiconductor layer 67 can be set to, for example, 30 nm, and the thickness of one semiconductor layer 68 can be set to, for example, 20 nm. The thickness of the uppermost dielectric layer 69 can be set to, for example, 50 nm. At this time, the semiconductor layers 67 and 68 formed on the exposed semiconductor substrate are epitaxially grown; however, the semiconductor layers 67 and 68 formed on the gate electrode film 66a or the side surface of the step D2 are not epitaxially grown and therefore become a polycrystalline film. However, because only the semiconductor layer 68 formed on the exposed semiconductor substrate is used as a transistor of a memory cell, this is practically no problem. The connection of each layer of the semiconductor layers 68 to the peripheral circuit can be controlled independently by forming an impurity diffusion layer, in which impurities are locally doped, at a different location for each layer of the stacked semiconductor layers 68.

Next, as shown in FIG. 30, the dielectric layer 69 and the semiconductor layers 67 and 68 of the peripheral circuit portion R22 are removed to expose the gate electrode film 66a of the peripheral circuit portion R22 by the lithography technique and the reactive ion etching technique. Next, the trench M3 that surrounds the memory cell portion R21 is formed by the lithography technique and the reactive ion etching technique. The formation of the trench M3 can be skipped.

Next, a planarization film 70 is formed on the semiconductor substrate 61 by a method such as the CVD. Then, the planarization film 70 is polished by a method such as the CMP with the gate electrode film 66a as a CMP stopper film to planarize the memory cell portion R21. As the planarization film 70, for example, an NSG film can be used.

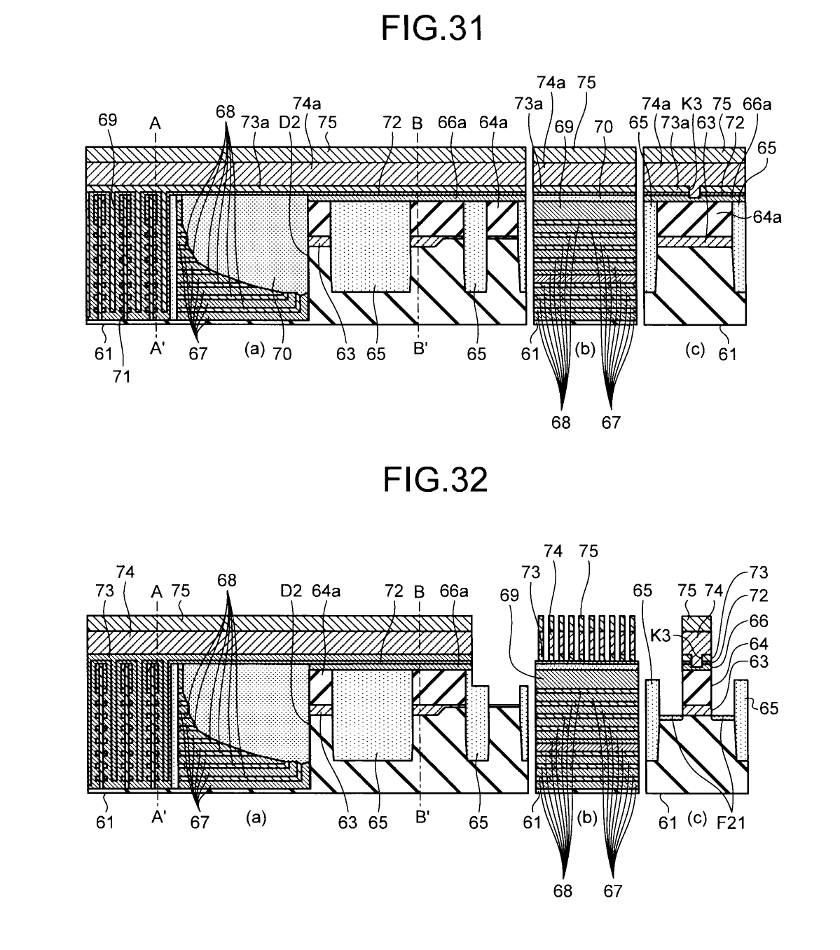

Next, as shown in FIG. 31, the stacked structure of the semiconductor layers 68 and the semiconductor layers 67 is processed into a fin shape by the lithography technique and the reactive ion etching to expose the side surfaces of the semiconductor layers 68. The interval of the fins can be set to, for example, 20 nm, and the width of this fin-shaped structure can be set to, for example, 15 nm. The half pitch of this fin-shaped structure can be set to, for example, 24 nm. At this time, a narrow space and a wide space are alternately repeated as the interval between the fins, and the narrow space is 20 nm and the wide space is 46 nm.

Next, a dielectric film 71 is formed on the whole surface of the substrate with a thickness of 12 nm by a conformal CVD method or ALD method. At this time, the narrow space between the fins is completely filled; however, the dielectric film 71 with a thickness of 12 nm is only conformally formed on the inner surfaces in the wide space between the fins. Next, the dielectric film 71 is etched back by about 15 nm by an isotropic etching in which hydrogen fluoride and ammonia are used so that the dielectric film 71 is remained only in the narrow space between adjacent fins.

Next, the semiconductor layers 67 are selectively removed by the wet etching to form a space between the semiconductor layers 68. For example, a mixture of hydrofluoric acid/nitric acid/acetic acid can be used as a chemical for the wet etching. Alternatively, the semiconductor layers 67 can be selectively removed by the chemical dry etching. Still alternatively, the semiconductor layers 67 can be selectively removed by a gas etching with chlorine gas.

Next, after performing a pretreatment with dilute hydrofluoric acid, a charge storage layer 72 is formed on the semiconductor layers 68 and the gate electrode film 66a by a method such as the CVD so that space between the semiconductor layers 68 formed by removing the semiconductor layers 67 and the side surfaces of the semiconductor layers 68 are covered. As the charge storage layer 72, for example, the ONO structure formed of the silicon oxide film/silicon nitride film/silicon oxide film can be used, and the film thickness at this time can be set to, for example, 3 nm, 2 nm, and 7 nm in order from the bottom. At this time, the space between the semiconductor layers 68 is filled with the charge storage layer 72, so that the fin-shaped structure composed of the semiconductor layers 68 and the charge storage layers 72 as the dielectric layers can be formed.

Next, a control gate electrode film 73a is formed on the charge storage layer 72 by a method such as the CVD. As the control gate electrode film 73a, for example, an n-type polycrystalline silicon film can be used. The thickness of the control gate electrode film 73a can be set to, for example, about 40 nm.

Next, the opening K3 that exposes the gate electrode film 66a of the peripheral circuit portion R22 is formed in the charge storage layer 72 and the control gate electrode film 73a by the lithography technique and the reactive ion etching.

Next, a control gate electrode film 74a connected to the gate electrode film 66a via the opening K3 is formed on the control gate electrode film 73a by a method such as the CVD. As the control gate electrode film 74a, for example, an n-type polycrystalline silicon film can be used. The thickness of the control gate electrode film 74a can be set to, for example, about 150 nm.

Next, a hard mask film 75 is formed on the control gate electrode film 74a by a method such as the CVD. As the hard mask film 75, for example, a silicon nitride film can be used. The thickness of the hard mask film 75 can be set to, for example, about 100 nm.

Next, as shown in FIG. 32, a patterning is performed on the hard mask film 75 to correspond to the planar shape of gate electrodes 64 and 66 and control gate electrodes 73 and 74 by the lithography technique and the reactive ion etching technique. Then, the reactive ion etching of the control gate electrode films 74a and 73a, the charge storage layer 72, and the gate electrode films 64a and 66a is collectively performed via the hard mask film 75 to form the control gate electrodes 73 and 74 arranged to intersect with the fin-shaped stacked structures of the semiconductor layers 68 and the dielectric layers (the charge storage layers 72) via the charge storage layer 72 in the memory cell portion R21 and form the gate stacked structure composed of the gate electrode 66, on the upper portion of which the control gate electrodes 73 and 74 electrically connected via the opening K3 is arranged, and the gate electrode 64 therebelow in the peripheral circuit portion R22. The half pitch of the control gate electrodes 73 and 74 of the memory cell portion R21 can be set to, for example, 24 nm.

Next, impurities are ion implanted in the semiconductor substrate 61 with the gate electrodes 64 and 66, on the upper portion of which the control gate electrodes 73 and 74 are arranged, as a mask to form the LDD layer F21 arranged on both sides of the gate electrodes 64 and 66 in the semiconductor substrate 61. It is applicable that the side faces of the gate electrodes 64 and 66 and the control gate electrodes 73 and 74 are oxidized by the rapid thermal oxidation that uses radicals generated from a hydrogen/oxygen mixed gas, and a polycrystalline silicon film that remains between the adjacent gate electrodes 64 and 66 and between the adjacent control gate electrodes 73 and 74 due to insufficient processing of the gate electrodes 64 and 66 and the control gate electrodes 73 and 74 is burned out, thereby preventing short circuits thereof and removing a process damage. The temperature for this radical oxidation can be set to, for example, 400° C.

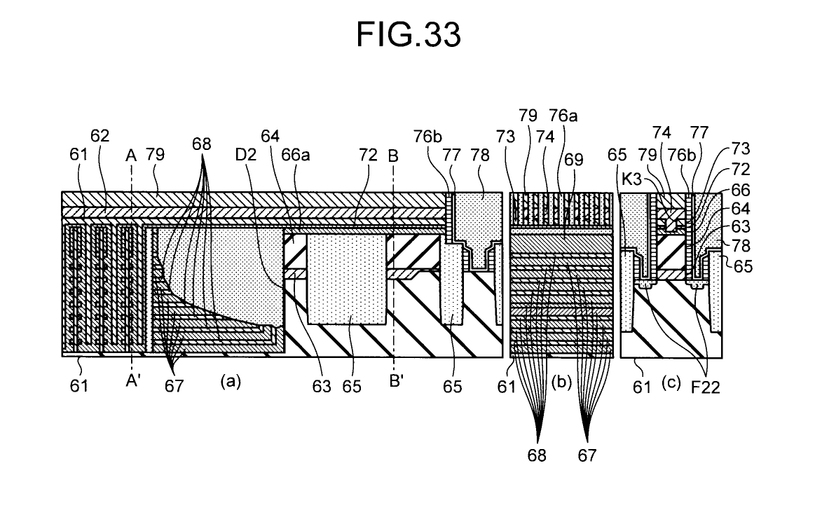

Next, as shown in FIG. 33, a dielectric film 76a filled between the control gate electrodes 73 and 74 of the memory cell portion R21 is formed and side walls 76b are formed on the side faces of the gate electrodes 64 and 66 and the control gate electrodes 73 and 74 of the peripheral circuit portion R22 by the ALD method. As the dielectric film 76a and the side wall 76b, for example, an NSG film can be used.

Then, impurities are ion implanted in the semiconductor substrate 61 with the gate electrodes 64 and 66, on the upper portion of which the control gate electrodes 73 and 74 are arranged, and the side walls 76b as a mask to form the high-concentration impurity diffusion layer F22 arranged on both sides of the gate electrodes 64 and 66 via the LDD layer F21 in the semiconductor substrate 61.

Next, an oxidation barrier film 77 is formed by a method such as the CVD. As the oxidation barrier film 77, for example, a silicon nitride film can be used.

Next, a dielectric film 78 is formed on the oxidation barrier film 77 by a method such as the CVD so that the gate electrodes 64 and 66 and the control gate electrodes 73 and 74 of the peripheral circuit portion R22 are filled. As the dielectric film 78, for example, a BPSG film can be used. Alternatively, the dielectric film 78 can be melted in a steam oxidation atmosphere so that the gate electrodes 64 and 66 and the control gate electrodes 73 and 74 of the peripheral circuit portion R22 are completely covered. Then, the dielectric film 78 is polished by the CMP to planarize the dielectric film 78.

Next, the dielectric film 78 is etched back and the hard mask film 75 and the oxidation barrier film 77 thereon are removed by the reactive ion etching to expose the control gate electrode 74. The etch-back amount of the dielectric film 78 can be set to, for example, 90 nm.

Next, a metal film is formed on the control gate electrode 74 by a method such as the sputtering. Then, the control gate electrode 74 is caused to react with the metal film by a method such as the RTA to form a silicide film 79 on the upper layer of the control gate electrode 74. Then, an unreacted metal film is removed by a method such as the wet etching. As the silicide film 79, for example, a nickel silicide film or a tungsten silicide film can be used. As a chemical for removing the unreacted metal film, the sulfuric acid/hydrogen peroxide mixture (SPM) can be used. In the following, a circuit of a flash memory is formed by the multilayer interconnection process.

According to the fourth embodiment, even when the number of the semiconductor layers 68 is large, the stacked structure in which the semiconductor layers 67 and the semiconductor layers 68 are alternately stacked can be processed into a fin shape by only one lithography process, and the control gate electrode 73 and 74 can be formed on both side surfaces of a plurality of layers of the semiconductor layers 68 by one lithography process. Therefore, a cell transistor having an ultra thin silicon on insulator (UTSOI) structure can be formed over a plurality of layers while suppressing the number of processes, which is insensitive to the short channel effect since control gate electrodes of UTSOI cell strongly dominate the channel, so that multi-level memory such as 2 bits/cell (=4 values) and 3 bits/cell (=8 values) can be realized easily and a memory density can be improved to eight times.

The embodiments of the present invention are explained above; however, the present invention is not limited to these embodiments and can be appropriately modified without departing from the gist of the present invention. Specifically, it is possible to allow the height variation within the range of a focal depth in the lithography technique, for example, the variation of about ±20 nm, between the upper surface of the stacked structure of the dielectric layers and the semiconductor layers in the memory cell portion and the upper surface of the gate electrode in the peripheral circuit portion, and the effect equivalent to the case of making the heights equal can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor storage device comprising:
a memory cell portion in which a stacked structure, in which dielectric layers and semiconductor layers are alternately stacked, is arranged in a fin shape on a semiconductor substrate, a control gate electrode is arranged to intersect with the fin-shaped stacked structure and a charge storage layer is arranged between the fin shape and the control gate electrode; and
a peripheral circuit portion in which a gate electrode is arranged on the semiconductor substrate via a gate dielectric film so that a height of an upper surface is substantially equal to the fin-shaped stacked structure.

2. The nonvolatile semiconductor storage device according to claim 1, wherein the fin-shaped stacked structure is formed in a region in which the gate electrode on the semiconductor substrate is removed.

3. The nonvolatile semiconductor storage device according to claim 1, wherein the fin-shaped stacked structure is arranged on a bottom portion of a trench formed in the semiconductor substrate.

4. The nonvolatile semiconductor storage device according to claim 3, further comprising:
a side wall formed on a side surface of the trench;
a concave portion provided between the fin-shaped stacked structure and the side wall; and
a planarization film that is filled in the concave portion to surround the fin-shaped stacked structure.

5. The nonvolatile semiconductor storage device according to claim 1, wherein
the charge storage layer and the control gate electrode are arranged also on the gate electrode of the peripheral circuit portion, and
the control gate electrode on the gate electrode is electrically connected to the gate electrode via an opening formed in the charge storage layer.

6. The nonvolatile semiconductor storage device according to claim 1, wherein the control gate electrode is formed to be opposed to both side surfaces of the fin-shaped stacked structure via the charge storage layer.

7. The nonvolatile semiconductor storage device according to claim 1, wherein
a dielectric film is filled between the fin-shaped stacked structure and an adjacent fin-shaped stacked structure on a side of one side surface of the fin-shaped stacked structure, and
the control gate electrode is formed to be opposed to another side surface of the fin-shaped stacked structure via the charge storage layer.

8. The nonvolatile semiconductor storage device according to claim 1, wherein the semiconductor layers are monocrystalline at least in the memory cell portion.

9. The nonvolatile semiconductor storage device according to claim 1, wherein impurities are locally doped in the semiconductor layers.

10. A method of manufacturing a nonvolatile semiconductor storage device comprising:
forming a gate electrode film of a peripheral circuit portion on a semiconductor substrate via a gate dielectric film;
forming a fin-shaped stacked structure, in which dielectric layers and semiconductor layers are alternately stacked so that a height of an upper surface is substantially equal to the gate electrode film, in a memory cell portion;
forming a charge storage layer on the fin-shaped stacked structure and the gate electrode film;
forming an opening, which exposes at least a part of the gate electrode film, in the charge storage layer;
forming a control gate electrode film electrically connected to the gate electrode film via the opening on the charge storage layer; and
forming a first control gate electrode arranged on the charge storage layer to intersect with the fin-shaped stacked structure in the memory cell portion and forming a gate electrode, on an upper portion of which a second control gate electrode electrically connected via the opening is arranged, in the peripheral circuit portion, by collectively performing a patterning on the control gate electrode film, the charge storage layer, and the gate electrode film.

11. The method according to claim 10, wherein
the forming the fin-shaped stacked structure, in which the dielectric layers and the semiconductor layers are alternately stacked, in the memory cell portion includes
stacking first semiconductor layers and second semiconductor layers, of which etching rate is smaller than the first semiconductor layers, alternately in the memory cell portion,
forming a space between the second semiconductor layers by removing the first semiconductor layers while leaving the second semiconductor layers in the memory cell portion, and
filling a dielectric film in the space.

12. The method according to claim 11, further comprising:
forming a side wall on a side face of the gate electrode film before the stacking the first semiconductor layers and the second semiconductor layers alternately in the memory cell portion; and
filling a planarization film in a concave portion between a stacked structure of the first semiconductor layers and the second semiconductor layers and the side wall so as to surround the stacked structure of the first semiconductor layers and the second semiconductor layers before removing the first semiconductor layers.

13. The method according to claim 10, wherein the fin-shaped stacked structure, in which the dielectric layers and the semiconductor layers are alternately stacked, is formed on the semiconductor substrate in a region where the gate electrode film and the gate dielectric film are removed so that the height of the upper surface is substantially equal to the gate electrode film.

14. The method according to claim 10, wherein the fin-shaped stacked structure, in which the dielectric layers and the semiconductor layers are alternately stacked, is formed on a bottom portion of a trench formed by removing the gate electrode film and the gate dielectric film and further more etching the semiconductor substrate so that the height of the upper surface is substantially equal to the gate electrode film.

15. The method according to claim 10, further comprising doping impurities locally in the semiconductor layers.

16. The method according to claim 11, further comprising doping impurities locally in the second semiconductor layers.

17. The method according to claim 11, wherein the stacking the first semiconductor layers and the second semiconductor layers includes performing a selective epitaxial growth of the first semiconductor layers and the second semiconductor layers on the semiconductor substrate.

18. The method according to claim 11, wherein the stacking the first semiconductor layers and the second semiconductor layers includes performing a blanket epitaxial growth with which the first semiconductor layers and the second semiconductor layers are epitaxially grown on the semiconductor substrate.

19. The method according to claim 14, further comprising forming an isolation trench to be an STI simultaneously with forming the trench in the semiconductor substrate of the memory cell portion.

20. The method according to claim 19, further comprising:
filling a dielectric film collectively in the trench of the semiconductor substrate of the memory cell portion and the isolation trench; and
forming a side wall on a side face of the trench of the semiconductor substrate of the memory cell portion by selectively etching back the dielectric film filled in the trench of the semiconductor substrate of the memory cell portion.
